(19) United States
(12) Patent Application Publication
(10) Pub. No.: US 2026/0068431 A1
(43) Pub. Date: Mar. 5, 2026

(54) DISPLAY DEVICE

(71) Applicant: Magnolia White Corporation, Tokyo (JP)

(72) Inventors: Takamitsu FUJIMOTO, Tokyo (JP); Sho YANAGISAWA, Tokyo (JP); Ryota TAKASAKI, Tokyo (JP); Hideyuki TAKAHASHI, Tokyo (JP); Tomokazu ISHIKAWA, Tokyo (JP)

(73) Assignee: Magnolia White Corporation, Tokyo (JP)

(21) Appl. No.: 19/317,163

(22) Filed: Sep. 3, 2025

(30) Foreign Application Priority Data
Sep. 4, 2024 (JP) 2024-152180

(51) Int. Cl. H10K 59/121; H10K 59/35; H10K 59/80; H10K 59/88

(52) U.S. Cl. CPC H10K 59/121; H10K 59/352; H10K 59/871; H10K 59/88

(57) ABSTRACT

According to one embodiment, a display device includes a display area where images are displayed, a surrounding area outside the display area, a lower electrode provided in the display area, a rib layer provided across the display area and the surrounding area and including a pixel aperture which overlaps with the lower electrode, and a first partition including a first lower portion provided on the rib layer in the surrounding area and having a conductive property, and a first upper portion provided on the first lower portion to protrude from a side surface of the first lower portion. The first partition includes a plurality of first segments formed in a cross shape and spaced apart from each other. The plurality of first segments do not have apertures.

### CROSS-REFERENCE TO RELATED APPLICATIONS

This application is based upon and claims the benefit of priority from Japanese Patent Application No. 2024-152180, filed Sep. 4, 2024, the entire contents of which are incorporated herein by reference.

### FIELD

Embodiments described herein relate generally to a display device.

### BACKGROUND

In recent years, display devices to which organic light emitting diodes (OLED) are applied as display elements have been put into practical use. In this type of display devices, a technique for improving the yield is required.

### BRIEF DESCRIPTION OF THE DRAWINGS

FIG. 1 is a diagram showing a configuration example of a display device according to a first embodiment.

FIG. 2 is a schematic plan view showing an example of a layout of subpixels.

FIG. 3 is a schematic cross-sectional view showing the display device along III-III line of FIG. 2.

FIG. 4 is a schematic plan view showing the display device according to the first embodiment.

FIG. 5 is a schematic plan view showing the display device according to the first embodiment with an area surrounded by a frame V in FIG. 4 enlarged.

FIG. 6 is a schematic plan view showing a first segment and a second segment of the display device according to the first embodiment.

FIG. 7 is a schematic cross-sectional view showing the display device according to the first embodiment along VII-VII line in FIG. 5.

FIG. 8 is a schematic plan view showing the display device according to the first embodiment with an area surrounded by a frame VIII in FIG. 4 enlarged.

FIG. 9 is a schematic plan view showing the second segment and a third segment of the display device according to the first embodiment.

FIG. 10 is a schematic cross-sectional view showing the display device along X-X line in FIG. 8.

FIG. 11 is a schematic plan view showing a mother substrate according to the present embodiment.

FIG. 12 is a schematic plan view showing a panel portion.

FIG. 13A is a schematic cross-sectional view showing a manufacturing process of the display device.

FIG. 13B is a schematic cross-sectional view showing a process following FIG. 13B.

FIG. 13C is a schematic cross-sectional view showing a process following FIG. 13C.

FIG. 13D is a schematic cross-sectional view showing a process following FIG. 13D.

FIG. 13E is a schematic cross-sectional view showing a process following FIG. 13E.

FIG. 13F is a schematic cross-sectional view showing a process following FIG. 13F.

FIG. 13G is a schematic cross-sectional view showing a process following FIG. 13G.

FIG. 13H is a schematic cross-sectional view showing a process following FIG. 13H.

FIG. 13I is a schematic cross-sectional view showing a process following FIG. 13I.

FIG. 13J is a schematic cross-sectional view showing a process following FIG. 13J.

FIG. 13K is a schematic cross-sectional view showing a process following FIG. 13K.

FIG. 14 is a diagram illustrating a method of applying a resin layer of the display device according to the first embodiment.

FIG. 15 is a diagram illustrating a method of applying a resin layer of the display device according to the first embodiment.

FIG. 16 is a diagram illustrating a method of applying a resin layer of the display device according to the first embodiment.

FIG. 17 is a schematic plan view showing a frame dummy area of a display device according to a comparative example.

FIG. 18 is a schematic cross-sectional view showing the display device according to the comparative example along XVIII-XVIII line in FIG. 17.

FIG. 19 is a schematic cross-sectional view showing the display device according to the comparative example along XVIII-XVIII line in FIG. 17.

FIG. 20 is a schematic plan view showing the display device according to a second embodiment with an area surrounded by a frame V in FIG. 4 enlarged.

FIG. 21 is a schematic cross-sectional view showing the display device according to the second embodiment along XXI-XXI line in FIG. 20.

FIG. 22 is a schematic plan view showing the display device according to the second embodiment with an area surrounded by a frame VIIII in FIG. 4 enlarged.

FIG. 23 is a diagram illustrating an extension direction of partitions.

FIG. 24 is a diagram showing a plurality of examples of substrates having different shapes.

FIG. 25 is a diagram illustrating a method of applying a resin layer of the display device according to the second embodiment.

FIG. 26 is a schematic plan view showing a first segment and a second segment of a display device according to a third embodiment.

FIG. 27 is a diagram illustrating the resin layer coating method for the display device according to the third embodiment.

FIG. 28 is a schematic plan view showing a first segment and a second segment of a display device according to a fourth embodiment.

FIG. 29 is a diagram illustrating a method of applying a resin layer of the display device according to the fourth embodiment.

FIG. 30 is a schematic plan view showing a first segment and a second segment of a display device according to a fifth embodiment.

FIG. 31 is a schematic plan view showing a first segment and a second segment of a display device according to a sixth embodiment.

FIG. 32 is a schematic plan view showing a first segment and a second segment of a display device according to a seventh embodiment.

### DETAILED DESCRIPTION

In general, according to one embodiment, a display device includes a display area where images are displayed, a surrounding area outside the display area, a lower electrode provided in the display area, a rib layer provided across the display area and the surrounding area and including a pixel aperture which overlaps with the lower electrode, and a first partition including a first lower portion provided on the rib layer in the surrounding area and having a conductive property, and a first upper portion provided on the first lower portion to protrude from a side surface of the first lower portion. The first partition includes a plurality of first segments formed in a cross shape and spaced apart from each other. The plurality of first segments do not have apertures.

According to another embodiment, a display device includes a substrate having a display area where images are displayed and a surrounding area provided outside the display area, a lower electrode provided above the substrate in the display area, a rib layer provided across the display area and the surrounding area and including a pixel aperture which overlaps with the lower electrode, and a plurality of first partitions including a first lower portion provided on the rib layer in the surrounding area and having a conductive property, and a first upper portion provided on the first lower portion to protrude from a side surface of the first lower portion. The plurality of first partitions radially extend from intersections of a center line of a width of the substrate in the first direction and a center line of a width of the substrate in a second direction intersecting the first direction.

According to yet another embodiment, a display device includes a substrate having a display area where images are displayed and a surrounding area provided outside the display area, a lower electrode provided above the substrate in the display area, a rib layer provided across the display area and the surrounding area and including a pixel aperture which overlaps with the lower electrode, and a plurality of first partitions including a first lower portion provided on the rib layer in the surrounding area and having a conductive property, and a first upper portion provided on the first lower portion to protrude from a side surface of the first lower portion. The surrounding area includes a first area located in a center line of a width of the substrate in the first direction, and a second area located in a center line of a width of the substrate in a second direction intersecting the first direction. Each of the plurality of first partitions extends in a straight line. A direction of extension of the first partitions in the first area is different from a direction of extension of the first partitions in the second area.

According to yet another embodiment, a display device includes a display area where images are displayed, a surrounding area outside the display area, a lower electrode provided in the display area, a rib layer provided across the display area and the surrounding area and including a pixel aperture which overlaps with the lower electrode, and a first partition including a first lower portion provided on the rib layer in the surrounding area and having a conductive property, and a first upper portion provided on the first lower portion to protrude from a side surface of the first lower portion. The first partition includes a first segment formed in a grating shape and including a plurality of first portions extending in a first direction and arranged at regular pitches in a second direction intersecting the first direction, a plurality of second portions extending in the second direction and arranged at regular pitches in the first direction, and a plurality of apertures surrounded by the plurality of first portions and the plurality of second portions. A width of the first portion in the second direction is equal to a width of the second portion in the first direction.

According to the embodiments, a display device capable of improving a yield can be provided.

Various embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are schematically illustrated in the drawings, compared to the actual modes. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

Incidentally, in the figures, an X-axis, a Y-axis and a Z-axis orthogonal to each other are described to facilitate understanding as needed. A direction along the X-axis is referred to as an X-direction, a direction along the Y-axis is referred to as a Y-direction, and a direction along the Z-axis is referred to as a Z-direction. In addition, viewing various elements in a direction parallel to the Z-direction is referred to as plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

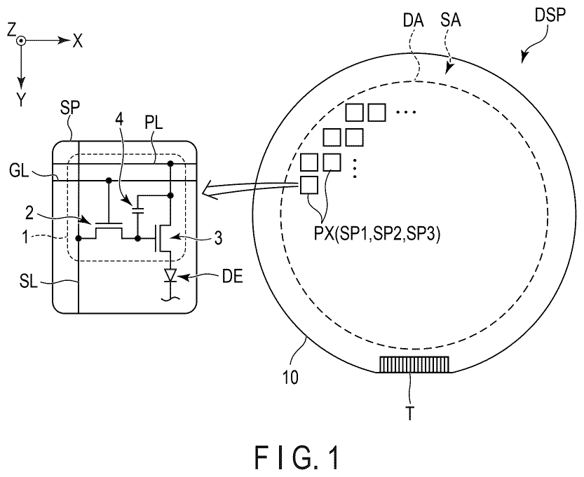

FIG. 1 is a diagram showing a configuration example of a display device DSP according to a first embodiment. The display device DSP comprises an insulating substrate 10. The substrate 10 has a display area DA where images are displayed, and a surrounding area SA around the display area DA. The substrate 10 may be glass or a resinous film having flexibility.

In the present embodiment, the substrate 10 has a circular shape in plan view. However, the shape of the substrate 10 in plan view is not limited to a circular shape, but may be the other shape such as a rectangle, a square, or an oval.

The display area DA comprises a plurality of pixels PX arrayed in matrix in an X-direction and a Y-direction. The pixels PX include a plurality of subpixels SP displaying different colors. In the present embodiment, it is assumed that each pixel PX includes a green subpixel SP1, a blue subpixel SP2, and a red subpixel SP3. However, the pixel PX may include a subpixel SP which exhibits the other color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit which supplies voltages and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements consisting of thin-film transistors.

A plurality of scanning lines GL which supply a scanning signal to the pixel circuit 1 of each subpixel SP, a plurality of signal lines SL which supply a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. A drain electrode of the drive transistor 3 is connected to the display element DE.

Incidentally, the configuration of the pixel circuit 1 is not limited to the example shown in the figure. For example, the pixel circuit 1 may comprise more thin-film transistors and more capacitors.

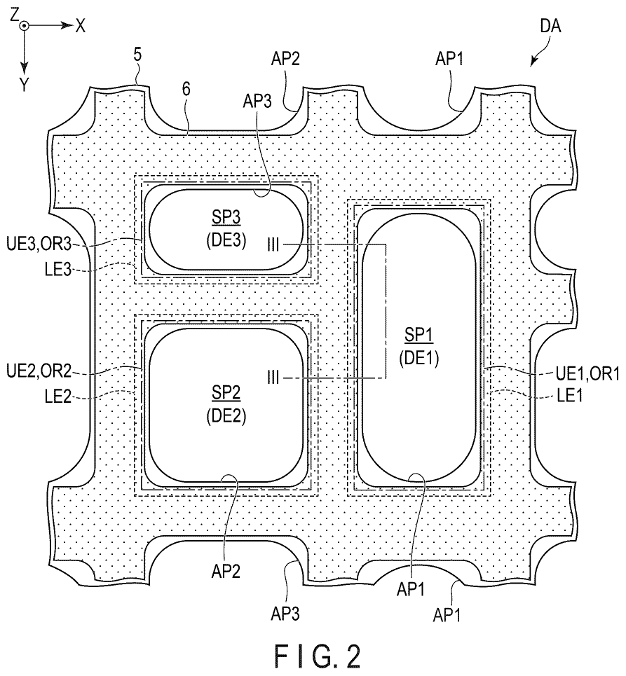

FIG. 2 is a schematic plan view showing an example of the layout of the subpixels SP1, SP2, and SP3. In the example shown in FIG. 2, each of the subpixels SP2 and SP3 is adjacent to the subpixel SP1 in the X-direction. Furthermore, the subpixels SP2 and SP3 are arranged in the Y-direction.

When the subpixels SP1, SP2, and SP3 are provided in this layout, a column in which the subpixels SP2 and SP3 are alternately provided in the Y-direction and a column in which a plurality of subpixels SP1 are repeatedly provided in the Y-direction are formed in the display area DA. These columns are alternately arranged in the X-direction. Incidentally, the layout of the subpixels SP1, SP2, and SP3 is not limited to the example shown in FIG. 2.

A rib layer 5 is provided in the display area DA. The rib layer 5 has pixel apertures AP1, AP2, and AP3 in the subpixels SP1, SP2, and SP3, respectively. In the example of FIG. 2, the pixel aperture AP1 is larger than the pixel aperture AP2, and the pixel aperture AP2 is larger than the pixel aperture AP3. In other words, among the subpixels SP1, SP2, and SP3, the aperture ratio of the subpixel SP1 is the largest, and the aperture ratio of the subpixel SP3 is the smallest. Incidentally, the size and shape of the pixel apertures AP1, AP2, and AP3 are not limited to the examples illustrated.

The subpixel SP1 comprises a lower electrode LE1, an upper electrode UE1, and an organic layer OR1 each overlapping with the pixel aperture AP1. The subpixel SP2 comprises a lower electrode LE2, an upper electrode UE2, and an organic layer OR2 each overlapping with the pixel aperture AP2. The subpixel SP3 comprises a lower electrode LE3, an upper electrode UE3, and an organic layer OR3 each overlapping with the pixel aperture AP3.

The parts of the lower electrode LE1, the upper electrode UE1, and the organic layer OR1, which overlap with the pixel aperture AP1, constitute a display element DE1 of the subpixel SP1. The parts of the lower electrode LE2, the upper electrode UE2, and the organic layer OR2, which overlap with the pixel aperture AP2, constitute a display element DE2 of the subpixel SP2. The parts of the lower electrode LE3, the upper electrode UE3, and the organic layer OR3, which overlap with the pixel aperture AP3, constitute a display element DE3 of the subpixel SP3. Each of the display elements DE1, DE2, and DE3 may further include a cap layer to be described later. The rib layer 5 surrounds each of these display elements DE1, DE2, and DE3.

A conductive partition 6 (second partition) is provided in the display area DA. The partition 6 is located above the rib layer 5 and overlaps with the rib layer 5 as a whole. In the example of FIG. 2, the partition 6 has a planar shape similar to that of the rib layer 5. In other words, the partition 6 comprises an aperture in each of the subpixels SP1, SP2, and SP3. It is considered from another viewpoint that the rib layer 5 and the partition 6 have a grating shape in plan view and surround each of the display elements DE1, DE2, and DE3. In addition, the partition 6 surrounds the pixel apertures AP1, AP2, and AP3. The partition 6 functions as lines which apply common voltage to the upper electrodes UE1, UE2, and UE3.

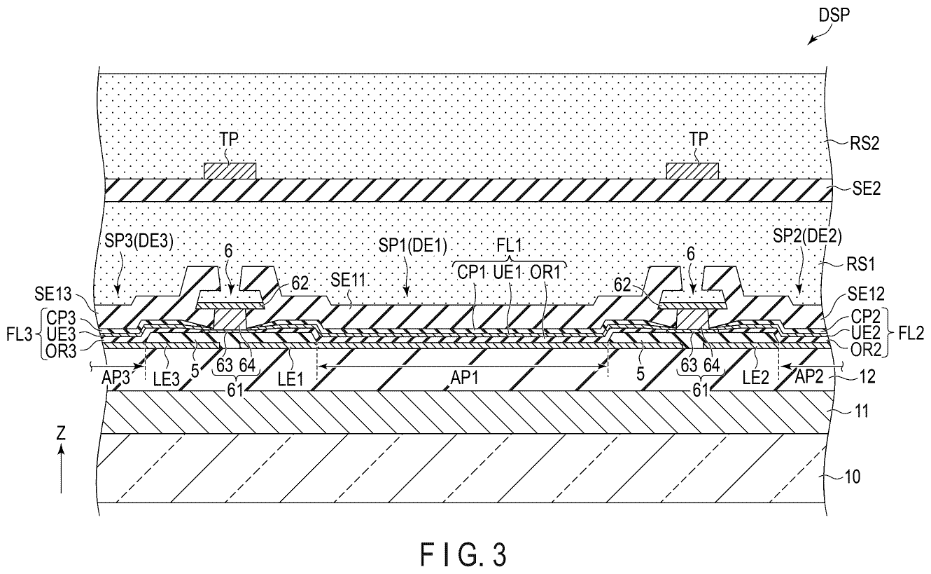

FIG. 3 is a schematic cross-sectional view showing the display device DSP along III-III line in FIG. 2. A circuit layer 11 is provided on the above-described substrate 10. The circuit layer 11 includes various circuits and lines such as the pixel circuit 1, the scanning line GL, the signal line SL, and the power line PL, which are shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2, and LE3 are provided on the organic insulating layer 12 and are spaced apart from each other. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross-section of FIG. 3, each of the lower electrodes LE1, LE2, and LE3 is connected to the pixel circuit 1 of the circuit layer 11 (i.e., the drain electrode of the drive transistor 3 shown in FIG. 1) through a contact hole provided in the organic insulating layer 12.

The partition 6 includes a conductive lower portion 61 (second lower portion) provided on the rib layer 5 and an upper portion 62 (second upper portion) provided on the lower portion 61. The upper portion 62 has a width greater than that of the lower portion 61. As a result, both the end portions of the upper portion 62 protrude beyond the side surfaces of the lower portion 61. This shape of the partition 6 is referred to as an overhang shape.

In the example of FIG. 3, the lower portion 61 has a bottom layer 63 provided on the rib layer 5, and a stem layer 64 provided on the bottom layer 63. For example, the bottom layer 63 is formed so as to be thinner than the stem layer 64. In the example of FIG. 3, the both end portions of the bottom layer 63 protrude from the side surfaces of the stem layer 64. In addition, the end portion of the bottom layer 63 is located between the end portion of the upper portion 62 and the side surface of the stem layer 64 in plan view. The upper portion 62 is provided on the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower portion 61 of the partition 6.

The display element DE1 includes a cap layer CP1 which covers the upper electrode UE1. The display element DE2 includes a cap layer CP2 which covers the upper electrode UE2. The display element DE3 includes a cap layer CP3 which covers the upper electrode UE3. The cap layers CP1, CP2, and CP3 function as optical adjustment layers for improving the extraction efficiency of the light emitted from the organic layers OR1, OR2, and OR3, respectively.

In the following descriptions, a multilayer body including the organic layer OR1, the upper electrode UE1, and the cap layer CP1 is referred to as a stacked film FL1, a multilayer body including the organic layer OR2, the upper electrode UE2, and the cap layer CP2 is referred to as a stacked film FL2, and a multilayer body including the organic layer OR3, the upper electrode UE3, and the cap layer CP3 is referred to as a stacked film FL3.

Sealing layers SE11, SE12, and SE13 which cover the stacked films FL1, FL2, and FL3, are provided in the subpixels SP1, SP2, and SP3, respectively. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the sealing layer SE11 located on the partition 6 between the subpixels SP1 and SP2 is spaced apart from the sealing layer SE12 located on the partition 6. In addition, the sealing layer SE11 located on the partition 6 between subpixels SP1 and SP3 is spaced apart from the sealing layer SE13 located on this partition 6. However, two of the sealing layers SE11, SE12, and SE13 may be in contact with each other above the partition 6.

For example, a gap is formed between each of the sealing layers SE11, SE12, and SE13 and the upper portion 62 of the partition 6. The stacked films FL1, FL2, and FL3 may be provided in at least parts of these gaps.

The sealing layers SE11, SE12, and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend to the surrounding area SA.

In the example of FIG. 3, a touch panel electrode TP for detecting the user's touch operation is provided on the sealing layer SE2. The touch panel electrode TP is formed of, for example, a metal material and has the same shape as the partition 6 in plan view.

A cover member such as a polarizer, a protective film, or a cover glass may be further provided above the resin layer RS2. This cover member may be bonded to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13, and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13, and SE2 is formed of silicon nitride. Each of the resin layers RS1 and RS2 is formed of, for example, a resinous material (organic insulating material) such as epoxy resin or acrylic resin.

Each of the lower electrodes LE1, LE2, and LE3 has a reflective layer, and a pair of conductive oxide layers covering upper and lower surfaces of the reflective layer. The reflective layer can be formed of, for example, a metal material excellent in light reflectivity, such as silver. Each of the conductive oxide layers can be formed of, for example, a transparent conductive oxide such as indium tin oxide (ITO), indium zinc oxide (IZO) or indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. For example, each of the organic layers OR1, OR2, and OR3 has a structure in which a hole injection layer, a hole transport layer, an electron blocking layer, a light emitting layer, a hole blocking layer, an electron transport layer and an electron injection layer are stacked in order in the Z-direction. However, each of the organic layers OR1, OR2, and OR3 may have the other structure such as a so-called tandem structure including a plurality of light emitting layers.

Each of the cap layers CP1, CP2, and CP3 has, for example, a multilayer structure in which a plurality of transparent layers are stacked. These transparent layers may include a layer formed of an inorganic material and a layer formed of an organic material. In addition, these transparent layers have refractive indices different from each other. For example, the refractive indices of these transparent layers are different from the refractive indices of the upper electrodes UE1, UE2, and UE3 and the refractive indices of the sealing layers SE11, SE12, and SE13. Incidentally, at least one of the cap layers CP1, CP2, and CP3 may be omitted.

Each of the bottom layer 63 and the stem layer 64 of the partition 6 is formed of a metal material. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. Incidentally, at least one of the bottom layer 63 and the stem layer 64 may have a multilayer structure consisting of a plurality of layers. Alternatively, the stem layer 64 may include a layer formed of an insulating material.

For example, the upper portion 62 of the partition 6 has a multilayer structure consisting of a lower layer formed of a metal material and an upper layer formed of conductive oxide. For example, titanium, titanium nitride, molybdenum, tungsten, a molybdenum-tungsten alloy or a molybdenum-niobium alloy can be used as the metal material forming the lower layer. For the conductive oxide forming the upper layer, for example, ITO or IZO can be used. Incidentally, the upper portion 62 may have a single-layer structure of a metal material. The upper portion 62 may further have a layer formed of an insulating material.

A common voltage is applied to the partition 6. This common voltage is applied to each of the upper electrodes UE1, UE2, and UE3 which are in contact with the side surfaces of the lower portions 61. A pixel voltage is applied to the lower electrodes LE1, LE2, and LE3 through the pixel circuits 1 provided in the subpixels SP1, SP2, and SP3, respectively, based on the video signals of the signal lines SL.

The organic layers OR1, OR2, and OR3 emit light based on the voltage application. More specifically, when a potential difference is formed between the lower electrode LE1 and the upper electrode UE1, the light emitting layer of the organic layer OR1 emits light of the green wavelength range. When a potential difference is formed between the lower electrode LE2 and the upper electrode UE2, the light emitting layer of the organic layer OR2 emits light of the blue wavelength range. When a potential difference is formed between the lower electrode LE3 and the upper electrode UE3, the light emitting layer of the organic layer OR3 emits light of the red wavelength range.

As another example, the light emitting layers of the organic layers OR1, OR2, and OR3 may emit light of the same color (for example, white). In this case, the display device DSP may comprise color filters that convert the light emitted from the light emitting layers into light of the colors corresponding to the subpixels SP1, SP2, and SP3. Alternatively, the display device DSP may comprise a layer including quantum dots which generate light exhibiting colors corresponding to subpixels SP1, SP2, and SP3 by the excitation caused by the light emitted from the light emitting layers.

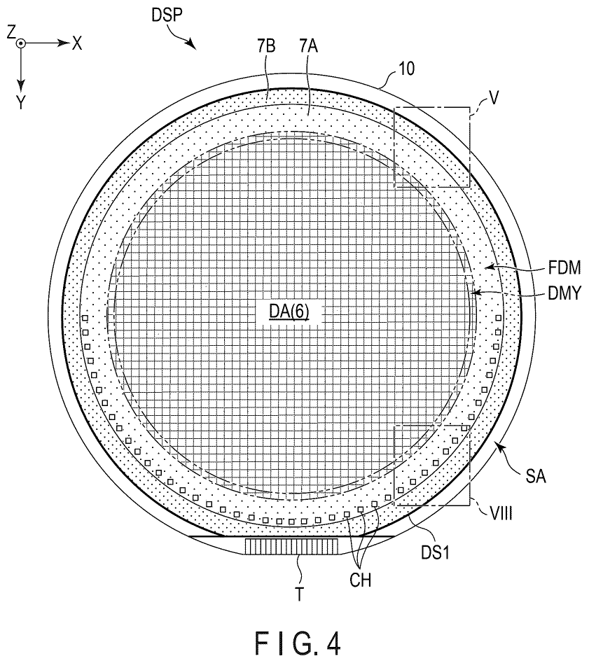

FIG. 4 is a schematic plan view showing the display device DSP according to the first embodiment. In this example, the peripheral area SA includes a dummy pixel area DMY, a frame dummy area FDM, a partition 7A (first partition), a partition 7B, and a dam structure DS1.

The dummy pixel area DMY surrounds the display area DA. The frame dummy area FDM surrounds the dummy pixel area DMY. The frame dummy area FDM is located between the dummy pixel area DMY and the dam structure DS1.

The partition 7A is located in the frame dummy area FDM. The partition 7B is located between the partition 7A and the dam structure DS1. In the example shown in FIG. 4, the partitions 7A and 7B surround the display area DA and the dummy pixel area DMY.

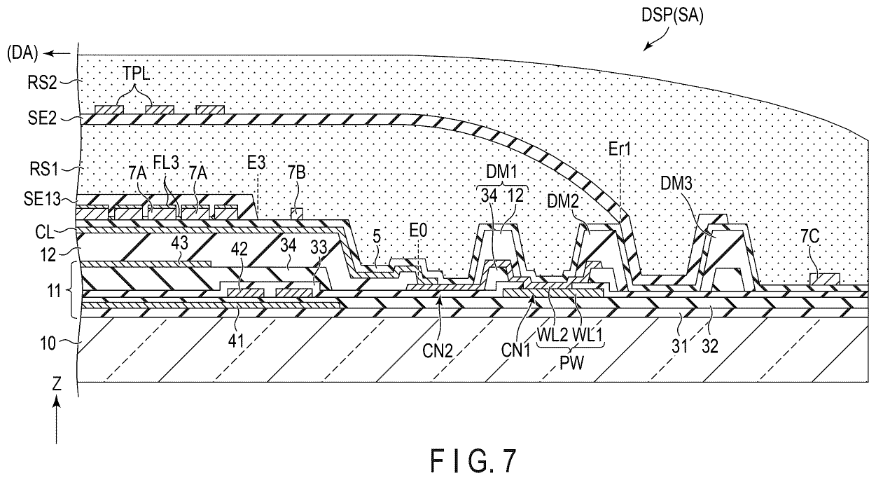

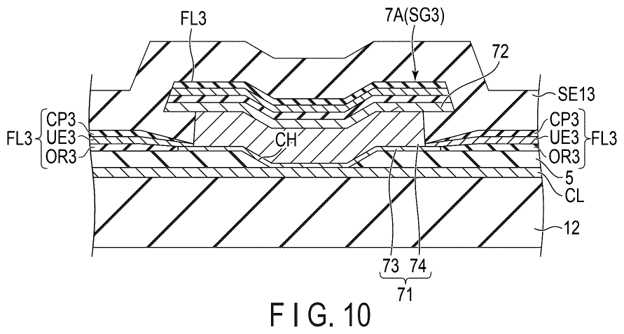

The partition 7A is connected to a lower conductive layer CL (see FIG. 10) via a plurality of contact holes CH. The conductive layer CL is connected to a power supply line PW (see FIG. 7). This power supply line PW is connected to the terminal portion T and supplies a common voltage to the partition 7A. The partition 6 provided in the display area DA is connected to the partition 7A. In other words, the common voltage of the power supply line PW is supplied to the partition 6 via the conductive layer CL and the partition 7A, and further supplied to the upper electrodes UE1, UE2, and UE3 in contact with the partition 6.

In the example shown in FIG. 4, the plurality of contact holes CH are provided in an arc shape on the terminal portion T side. The plurality of contact holes CH overlap with the partition 7A.

The dam structure DS1 is located outside the partition 7B and surrounds the display area DA, the dummy pixel area DMY, the frame dummy area FDM, and the partition 7B. The terminal portion T is located outside the dam structure DS1.

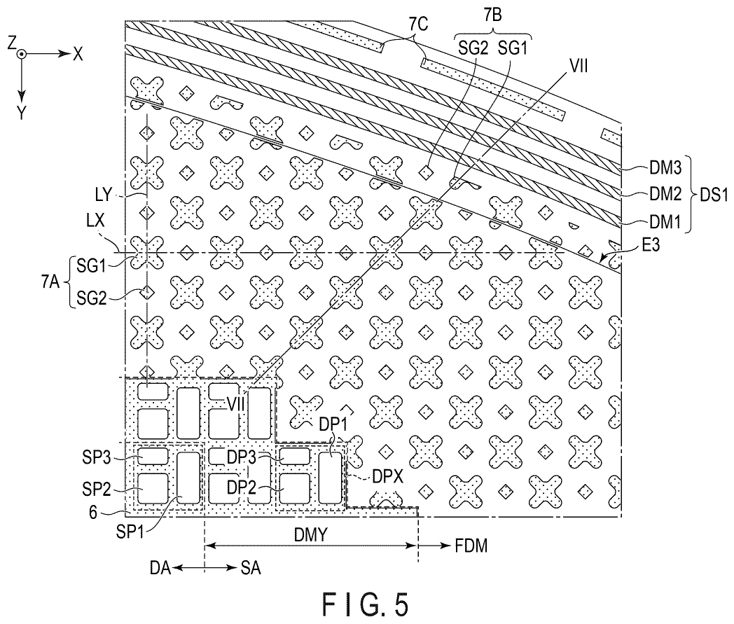

FIG. 5 is a schematic plan view showing the display device DSP according to the first embodiment with an area surrounded by a frame V in FIG. 4 enlarged. The plurality of dummy pixels DPX are provided in the dummy pixel area DMY. For example, each dummy pixel DPX includes dummy subpixels DP1, DP2, and DP3. The dummy subpixels DP1, DP2, and DP3 have structures similar to those of the subpixels SP1, SP2, and SP3, respectively.

In other words, the sub-pixel DP1 includes the lower electrode LE1, the organic layer OR1, the upper electrode UE1, the cap layer CP1, and the sealing layer SE11. In addition, the dummy subpixel DP2 includes the lower electrode LE2, the organic layer OR2, the upper electrode UE2, the cap layer CP2, and the sealing layer SE12. Furthermore, the dummy subpixel DP3 includes the lower electrode LE3, the organic layer OR3, the upper electrode UE3, the cap layer CP3, and the sealing layer SE13.

However, the dummy subpixels DP1, DP2, and DP3 are configured not to emit light. This configuration can be realized by, for example, cutting a part of the pixel circuit 1 in each of the dummy subpixels DP1, DP2, and DP3. In addition, the pixel apertures AP1, AP2, and AP3 may be omitted in the dummy subpixels DP1, DP2, and DP3. Accordingly, the rib layer 5 is interposed between the organic layers OR1, OR2, and OR3 and the lower electrodes LE1, LE2, and LE3, and the voltage required to emit light from the organic layers OR1, OR2, and OR3 is not applied to the organic layers.

A part of the partition 6 is located in the dummy pixel area DMY and surrounds each of the plurality of dummy subpixels DPX. More specifically, the partition 6 surrounds each of the dummy subpixels DP1, DP2, and DP3. The shape and layout of the aperture of the partition 6 in each of the dummy subpixels DP1, DP2, and DP3 are similar to those of the aperture of the partition 6 in each of the subpixel SP1, SP2, and SP3.

The partition 7A includes a plurality of first segments SG1 and a plurality of second segments SG2 provided in the frame dummy area FDM. The plurality of first segments SG1 are spaced apart from the plurality of second segments SG2. In the example shown in FIG. 5, the plurality of first segments SG1 are formed in a cross shape and are spaced apart from each other. In addition, the plurality of second segments SG2 are formed in a square shape and are spaced apart from each other.

The plurality of first segments SG1 and the plurality of second segments SG2 are arranged alternately in the X-direction. In the example shown in FIG. 5, the plurality of first segments SG1 and the plurality of second segments SG2 are arranged alternately on a straight line LX extending in the X-direction. The plurality of first segments SG1 and the plurality of second segments SG2 are arranged alternately in the Y-direction. In the example shown in FIG. 5, the plurality of first segments SG1 and the plurality of second segments SG2 are arranged alternately on a straight line LY extending in the Y-direction.

The partition 7B includes the first segment SG1 and the second segment SG2, similarly to the partition 7A.

The dam structure DS1 includes a dam portion DM1 surrounding the partitions 7A and 7B, a dam portion DM2 surrounding the dam portion DM1, and a dam portion DM3 surrounding the dam portion DM2. The partitions 7A and 7B are spaced apart from the dam portion DM1. Incidentally, the number of dam portions provided in the dam structure DS1 is not limited to three. For example, the dam portions DM1, DM2, and DM3 have a circular shape surrounding the display area DA.

In the example shown in FIG. 5, a plurality of partitions 7C are provided outside the dam portion DM3. These partitions 7C are spaced apart from each other and arranged along the dam portion DM3.

An end portion E3 of the sealing layer SE13 is provided in the frame dummy area FDM. The end portion E3 is located between the partitions 7A and 7B. In one example, the end portion E3 does not overlap with the partitions 7A and 7B.

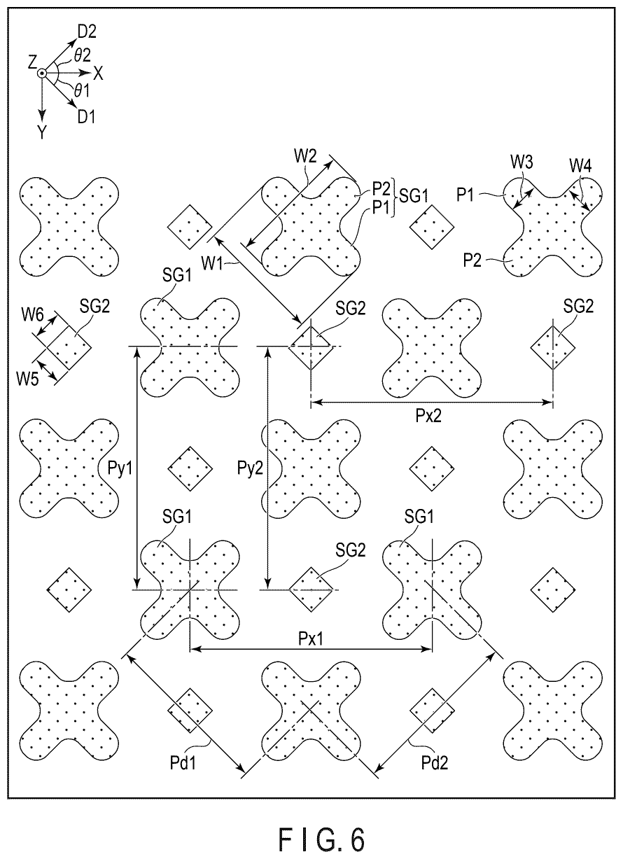

FIG. 6 is a schematic plan view showing the first segments SG1 and the second segments SG2 of the display device DSP according to the first embodiment.

Each first segment SG1 has a first portion P1 and a second portion P2. In the example shown in FIG. 6, the first portion P1 extends along a direction D1 inclined at an angle θ1 clockwise relative to the X-direction. In addition, the second portion P2 extends along a direction D2 inclined at an angle θ2 counterclockwise relative to the X-direction.

A pitch Px1 of the first segments SG1 adjacent in the X-direction is equal to a pitch Py1 of the first segments SG1 adjacent in the Y-direction (Px1=Py1). A pitch Pd1 of the first segments SG1 adjacent in the direction D1 is equal to a pitch Pd2 of the first segments SG1 adjacent in the direction D2 (Pd1=Pd2).

A pitch Px2 of the second segments SG2 adjacent in the X-direction is equal to a pitch Py2 of the second segments SG2 adjacent in the Y-direction (Px2=Py2). In the example shown in FIG. 6, the plurality of first segments SG1 and the plurality of second segments SG2 are arranged at regular pitches. In other words, the pitches Px1, Py1, Px2, and Py2 are all equal (Px1=Py1=Px2=Py2).

In the example shown in FIG. 6, the width W1 of the first portion P1 in the direction D1 is equal to the width W2 of the second portion P2 in the direction D2 (W1=W2). In addition, the width W3 of the first portion P1 in the direction D2 is equal to the width W4 of the second portion P2 in the direction D1 (W3=W4). Furthermore, the width W5 of the second segment SG2 in the direction D1 is equal to the width W6 of the second segment SG2 in the direction D2 (W5=W6).

FIG. 7 is a schematic cross-sectional view showing the display device DSP according to the first embodiment along VII-VII line in FIG. 5.

The circuit layer 11 shown in FIG. 3 includes inorganic insulating layers 31, 32, and 33 formed of an inorganic insulating material, an organic insulating layer 34 formed of an organic insulating material, and metal layers 41, 42, and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

Each of the dam portions DM1, DM2, and DM3 protrudes to the upper side of the substrate 10. In the example of FIG. 7, the dam portion DM1 is formed by the organic insulating layers 12 and 34. The dam portions DM2 and DM3 are also formed by the organic insulating layers 12 and 34. In other words, in the present embodiment, the dam portions DM1, DM2, and DM3 are formed of the same material as the organic insulating layers 12 and 34 and are formed in the same layer as the organic insulating layers 12 and 34.

The power supply line PW to which the common voltage is applied is provided under the dam portions DM1 and DM2. The power supply line PW has a first line WL1 formed by the metal layer 42, and a second line WL2 formed by the metal layer 43.

In the example of FIG. 7, the first line WL1 and the second line WL2 are in contact with each other in a contact portion CN1 located between the dam portions DM1 and DM2. The second line W2 is partially located between the organic insulating layers 12 and 34 in each of the dam portions DM1 and DM2.

The conductive layer CL with a conductive property, which is connected to the power supply line PW, and the rib layer 5 are further provided in the surrounding area SA. For example, the conductive layer CL is formed of the same material by the same process as the above-described lower electrodes LE1, LE2, and LE3.

The conductive layer CL is located on the display area DA side (the left side in the figure) relative to the dam portion DM1 and covers the organic insulating layer 12. The conductive layer CL is in contact with the second line WL2 of the power line PW at a contact portion CN2. The contact portion CN2 is located between an end portion E0 of the organic insulating layer 12 and the dam portion DM1 in plan view. The rib layer 5 continuously covers the conductive layer CL and the dam portions DM1, DM2, and DM3.

The partitions 7A and 7B are provided on the rib layer 5. The stacked film FL3 is provided on the partitions 7A and between the partitions 7A spaced apart from each other. The partitions 7A and the stacked film FL3 are covered with the sealing layer SE13. Incidentally, instead of the stacked film FL3 and the sealing layer SE13, the stacked film FL1 and the sealing layer SE11, or the stacked film FL2 and the sealing layer SE12 may cover the partitions 7A. The partitions 7B are not covered with the stacked film FL3 and the sealing layer SE13.

The resin layer RS1, the sealing layer SE2, and resin layer RS2 shown in FIG. 3 are provided above the sealing layer SE13. In the illustrated example, the resin layer RS1 directly covers the partition 7B, and the resin layer RS2 directly covers the partition 7C. A touch panel line TPL connected to the touch panel electrode TP shown in FIG. 3 is provided on the sealing layer SE2. For example, the touch panel line TPL is formed of the same material as the touch panel electrode TP.

When the display device DSP is manufactured, the dam portions DM1, DM2, and DM3 play a role of damming up the resin layer RS1 to be cured. In the example of FIG. 7, an end portion Er1 of the resin layer RS1 is located above the dam portion DM1. In other words, the resin layer RS1 covers the dam portion DM1 and a part of the dam portion DM2. However, the position of the end portion Er1 is not limited to this example.

The sealing layer SE2 covers the end portion Er1 of the resin layer RS1. The sealing layer SE2 is in contact with the rib layer 5 in an area located on an external side (the right side in the figure) relative to the end portion Er1. In the example of FIG. 7, the sealing layer SE2 is removed near the dam portion DM3. The resin layer RS1 is covered with the sealing layer SE13, the rib layer 5, and the sealing layer SE2. Impregnation of moisture into the resin layer RS1 is thereby suspended.

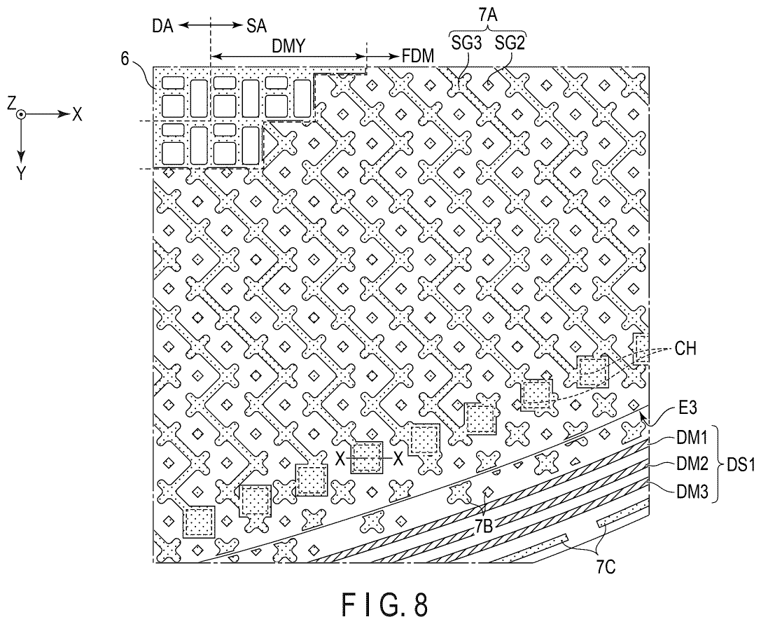

FIG. 8 is a schematic plan view showing the display device DSP according to the first embodiment with an area surrounded by a frame VIII in FIG. 4 enlarged. The partition 7A further includes a plurality of third segments SG3. The third segments SG3 have a shape in which the plurality of first segments SG1 are connected in a staircase-like manner. The second segments SG2 are provided between the adjacent third segments SG3.

The third segments SG3 overlap with the contact holes CH and are connected to the partition 6 of the dummy pixel area DMY. Therefore, the common voltage supplied to the terminal portion T is supplied to the third segments SG3 via the contact holes CH and then supplied from the third segments SG3 to the partition 6 and the upper electrodes UE1, UE2, and UE3.

In one example, the plurality of third segments SG3 are located in a lower half area of the frame dummy area FDM (i.e., the area on the terminal portion T side), and the plurality of first segments SG1 are provided in an upper half area thereof. Incidentally, the third segments SG3 may be provided in the upper half area.

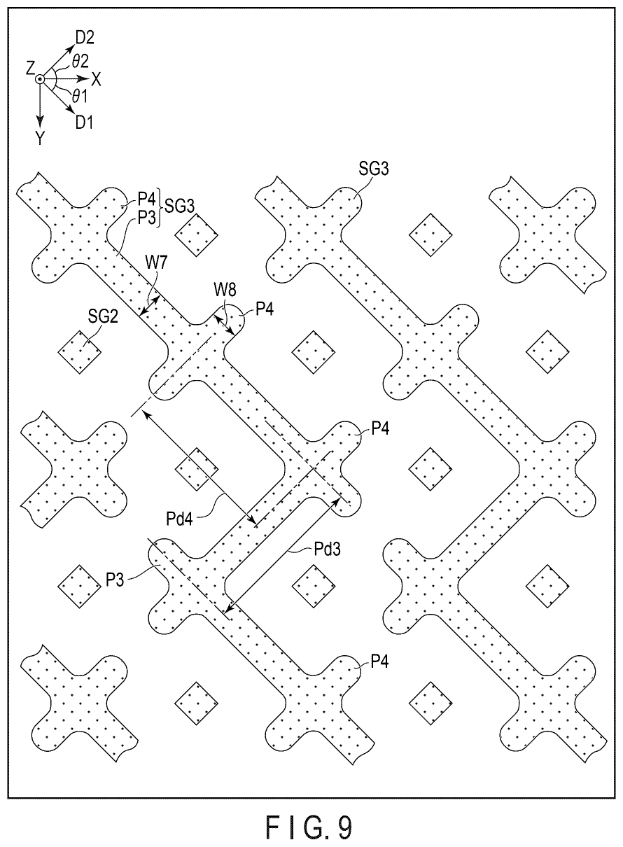

FIG. 9 is a schematic plan view showing the second segments SG2 and the third segments SG3 of the display device DSP according to the first embodiment.

Each third segments SG3 includes a plurality of third portions P3 and a plurality of fourth portions P4. In the example shown in FIG. 9, the third portions P3 extend in the direction D1. In addition, the fourth portions P4 extend in the direction D2.

A pitch Pd3 of the third portions P3 adjacent in the direction D2 is equal to a pitch Pd4 of the fourth portions P4 adjacent in the direction D1 (Pd3=Pd4). In one example, the pitch Pd3 is equal to the pitch Pd2 shown in FIG. 6 (Pd3=Pd2). In addition, the pitch Pd4 is equal to the pitch Pd1 shown in FIG. 6 (Pd4=Pd1).

A width W7 of the third portion P3 in the direction D2 is equal to a width W8 of the fourth portion P4 in the direction D1 (W7=W8). In one example, the width W7 is equal to the width W3 shown in FIG. 6 (W7=W3). In one example, the width W8 is equal to the width W4 shown in FIG. 6 (W8=W4).

FIG. 10 is a schematic cross-sectional view showing the display device DSP along X-X line in FIG. 8. In FIG. 10, the illustration of the elements provided below the organic insulating layer 12 is omitted.

In the surrounding area SA, the conductive layer CL is provided on the organic insulating layer 12. The rib layer 5 is provided on the conductive layer CL. The rib layer 5 includes contact holes CH that penetrate the conductive layer CL.

The partition 7A includes a conductive lower portion 71 (first lower portion) provided on the rib layer 5 and an upper portion 72 (first upper portion) provided on the lower portion 71. The upper portion 72 has a width which is greater than that of the lower portion 71. Accordingly, both end portions of the upper portion 72 protrude relative to side surfaces of the lower portion 71. A part of the lower portion 71 of the third segment SG3, of the partition 7A, is in contact with the conductive layer CL through the contact hole CH.

The lower portion 71 includes a bottom layer 73 provided on the rib layer 5, and a conductive stem layer 74 provided on the bottom layer 73. For example, the bottom layer 73 is formed so as to be thinner than the stem layer 74. A part of the bottom layer 73 of the third segment SG3, of the partition 7A, is in contact with the conductive layer CL through the contact hole CH. Each of the partitions 7B and 7C shown in FIG. 5 includes the lower portion 71 and the upper portion 72, similarly to the partition 7A.

In the surrounding area SA, the organic layer OR3 is provided on the rib layer 5. The upper electrode UE3 is provided on the organic layer OR3. The cap layer CP3 is provided on the upper electrode UE3. The sealing layer SE13 is provided on the cap layer CP3 and covers the partition 7A.

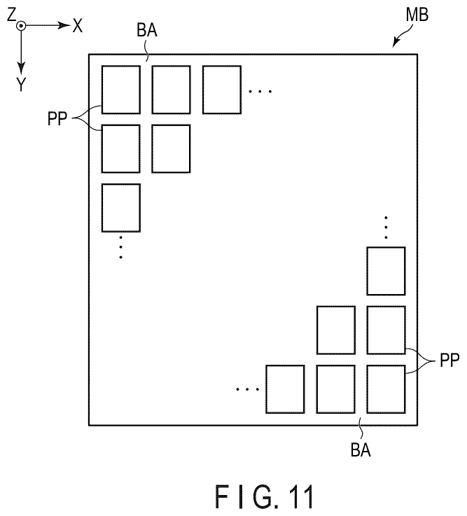

FIG. 11 is a schematic plan view showing a mother substrate MB (mother substrate for display device) according to the present embodiment. The mother substrate MB has, for example, a rectangular shape as shown in the figure, but may have the other shape such as a circle.

The mother substrate MB comprises a plurality of panel portions PP provided in matrix, and a margin area BA around these panel portions PP. In the example of FIG. 11, the panel portions PP are arranged via the margin area BA in the X-direction and the Y-direction. However, the layout form of the plurality of panel portions PP in the mother substrate MB is not limited to this example. As another example, several panel portions PP may be arranged without intervention of the margin area BA.

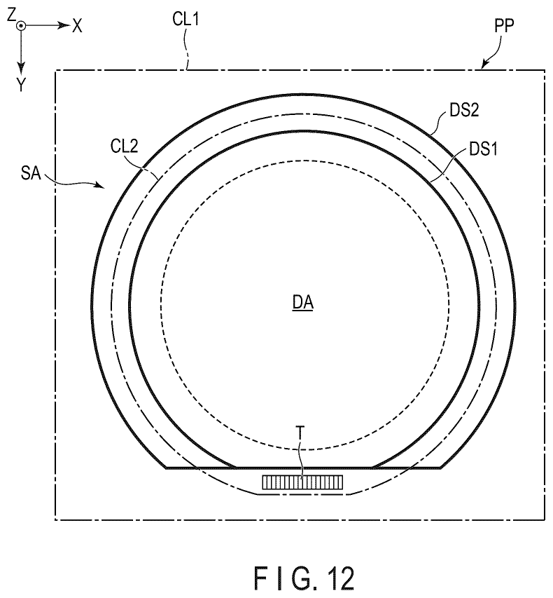

FIG. 12 is a schematic plan view showing the panel portion PP. The outer shape of the panel portion PP corresponds to a cut line CL1 for cutting the panel portion PP from the mother substrate MB.

The panel portion PP has the display area DA and the surrounding area SA as described above. The surrounding area SA in the panel portion PP corresponds to the area located between the display area DA and the cut line CL1.

The surrounding area SA further includes a cut line CL2 which is the outer shape of the substrate 10 of the display device DSP. When the display device DSP is manufactured, the panel portion PP is cut out from the mother substrate MB along the cut line CL1. Furthermore, the display device DSP is cut out from the panel sections PP along the cut line CL2.

The panel portion PP comprises a dam structure DS2 in addition to the above-described dam structure DS1. The dam structure DS2 functions to dam up the resin layer RS2 to be cured. For example, the dam structure DS2 includes a plurality of dam portions formed by the organic insulating layers 12 and 34, similarly to the dam portions DM1, DM2, and DM3.

The dam structure DS1 is located between the cut line CL2 and the display area DA and surrounds the display area DA. The dam structure DS2 is located between cut lines CL1 and CL2 and surrounds the cut line CL2. In the example of FIG. 12, the dam structures DS1 and DS2 join together near the terminal portion T, and this joined portion passes through an area located between the terminal portion T and the display area DA.

A large part of the cut line CL2 is located between the dam structures DS1 and DS2. In the example of FIG. 12, however, the cut line CL2 is located outside the dam structures DS1 and DS2 near the terminal portion T. In other words, the cut line CL2 intersects the dam structure DS2 near the terminal portion T.

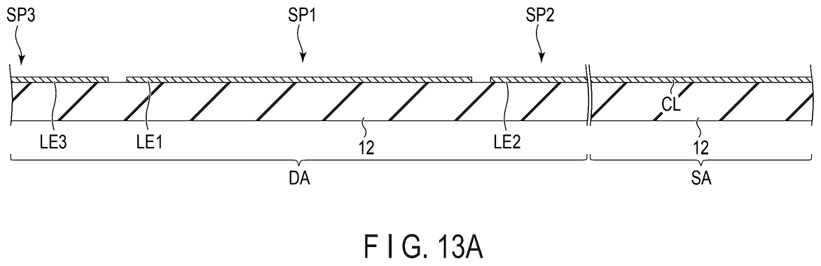

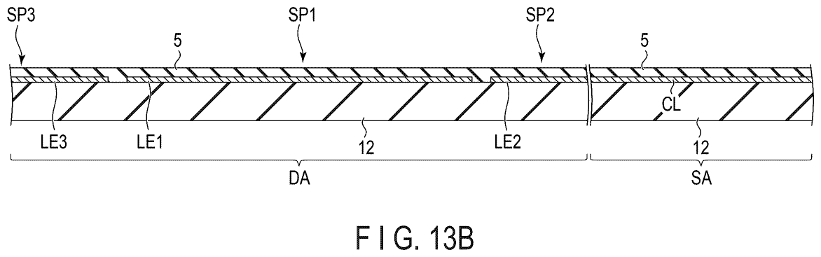

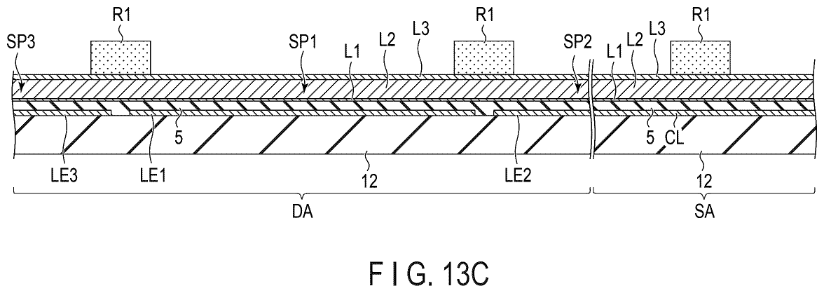

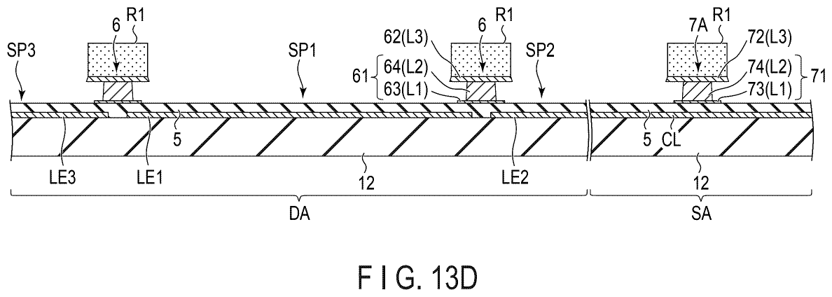

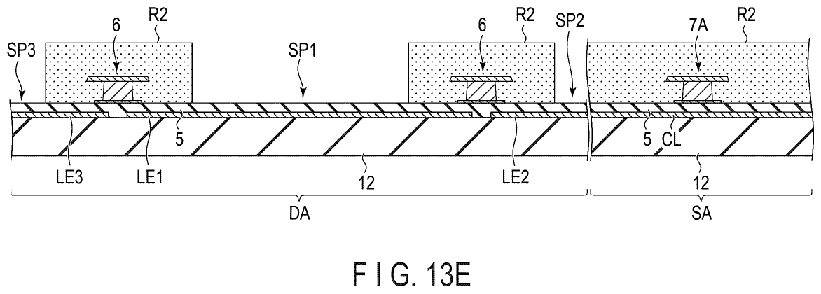

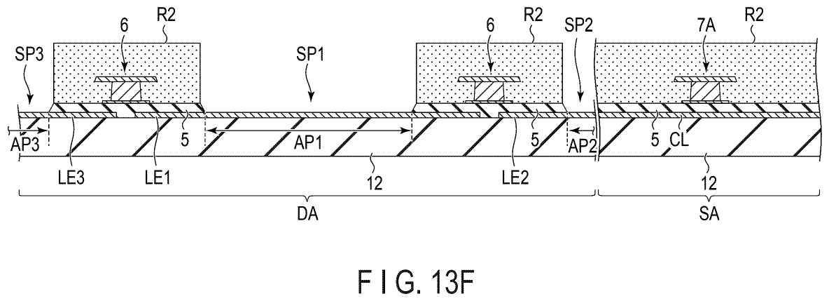

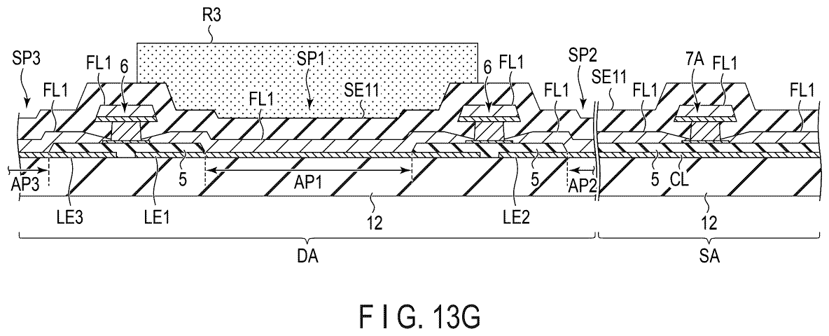

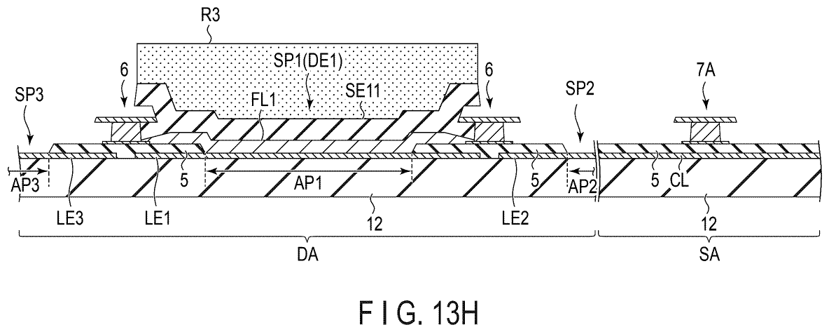

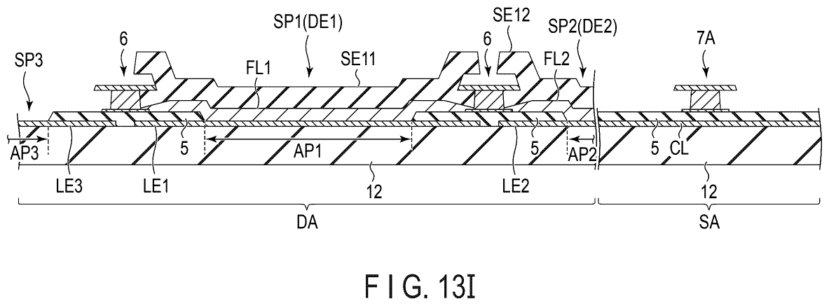

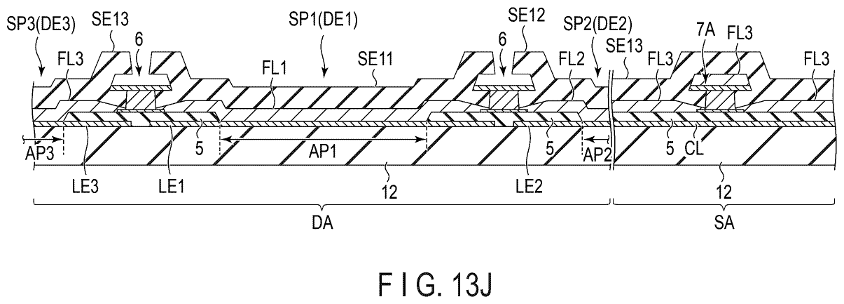

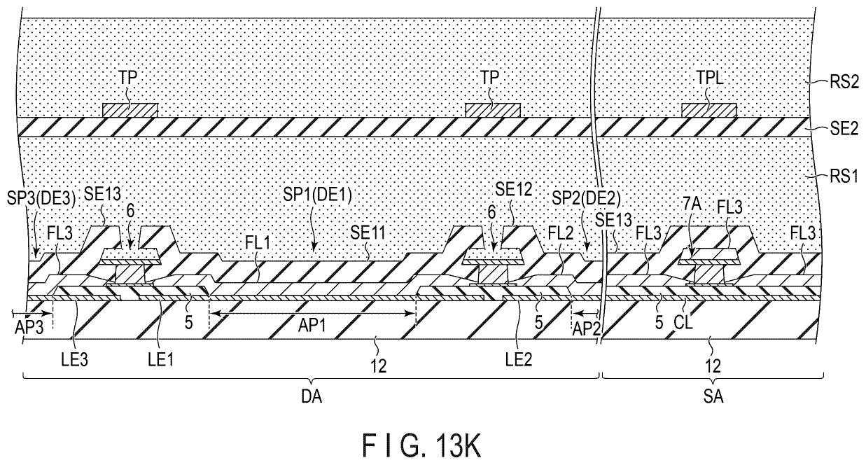

Next, an example of a method of manufacturing the display device DSP will be described. Each of FIG. 13A to FIG. 13K is a schematic cross-sectional view showing a manufacturing process of the display device DSP. In FIG. 13A to FIG. 13K, illustration of the elements located below the organic insulating layer 12 is omitted.

To form the panel portion PP, first, the circuit layer 11 and the organic insulating layer 12 are formed on the substrate 10 of the mother substrate MB. Next, as shown in FIG. 13A, the lower electrodes LE1, LE2, and LE3 are formed on the organic insulating layer 12 in the display area DA. In addition, the conductive layer CL is formed on the organic insulating layer 12, in the surrounding area SA.

Subsequently, as shown in FIG. 13B, the rib layer 5 which covers the lower electrodes LE1, LE2, and LE3 and the conductive layer CL is formed in the entire mother substrate MB. At this time, the pixel aperture AP1, AP2, and AP3 are not provided in the rib layer 5. The rib layer 5 can be formed by chemical vapor deposition (CVD).

After the formation of the rib layer 5, a process for forming the partitions 6 and 7A is performed. As shown in FIG. 13C, a first layer L1 which is processed to be the bottom layers 63 and 73, a second layer L2 which is processed to be the stem layers 64 and 74, a third layer L3 which is processed to be the upper portions 62 and 72 are formed in order in the entire mother substrate MB. Furthermore, a resist R1 is provided on the third layer L3. The resist R1 is patterned in the shape of the partitions 6 and 7A. The first layer L1, the second layer L2, and the third layer L3 can be formed by, for example, sputtering.

After that, the first layer L1, the second layer L2, and the third layer L3 are patterned using the resist R1 as a mask. In one example, the first layer L1 is formed of titanium nitride, the second layer L2 is formed of aluminum, and the third layer L3 is formed of titanium and ITO. In this case, a dry etching process of removing the portions of the first layer L1, second layer L2, and third layer L3, which are exposed from the resist R1, and a wet etching process of reducing the width of the second layer L2, are performed. Incidentally, the etching processes are selected appropriately according to the structures and materials of the partitions 6 and 7A.

After that, as shown in FIG. 13D, the partitions 6 are formed in the display area DA, and the partition 7A is formed in the surrounding area SA. After the formation of the partitions 6 and 7A, the resist R1 is removed (peeled off). Incidentally, the partitions 7B and 7C shown in FIG. 5 are formed in the same processes as the portions 6 and 7A.

Next, a process of providing the pixel apertures AP1, AP2, and AP3 in the display area DA is performed. In this process, a resist R2 which covers the partitions 6 and 7A is formed as shown in FIG. 13E. Furthermore, dry etching for the rib layer 5 is performed using the resist R2 as a mask. Accordingly, as shown in FIG. 13F, the pixel apertures AP1, AP2, and AP3 from which the lower electrodes LE1, LE2, and LE3 are exposed in the display area DA are formed in the rib layer 5. After the above-described dry etching, the resist R2 is removed (peeled off).

After that, a process for forming the display element DE1 is performed. To form the display element DE1, first, the stacked film FL1 and the sealing layer SE11 are formed as shown in FIG. 13G. The stacked film FL1 includes the organic layer OR1 which is in contact with the lower electrode LE1 through the pixel aperture AP1, the upper electrode UE1 which covers the organic layer OR1, and the cap layer CP1 which covers the upper electrode UE1, as shown in FIG. 3. The organic layer OR1, the upper electrode UE1, and the cap layer CP1 can be formed by, for example, vapor deposition. In addition, the sealing layer SE11 can be formed by, for example, CVD.

The stacked film FL1 and the sealing layer SE11 are formed in the entire mother substrate MB including the surrounding area SA and the margin area BA as well as the display area DA of each panel portion PP. The stacked film FL1 is divided into a plurality of parts by the partitions 6 and 7A having an overhang shape. The sealing layer SE11 continuously covers each of the divided parts of the stacked film FL1 and the partitions 6 and 7A.

Next, the stacked film FL1 and the sealing layer SE11 are patterned. In this patterning, a resist R3 is provided on the sealing layer SE11 as shown in FIG. 13G. The resist R3 covers the subpixel SP1 and a part of the partition 6 around the subpixel SP1.

After that, an etching process using the resist R3 as a mask is performed. Parts of the stacked film FL1 and the sealing layer SE11, which are exposed from the resist R3, are removed as shown in FIG. 13H. In other words, parts of the stacked film FL1 and the sealing layer SE11, which overlap with the lower electrode LE1, remain and the other parts are removed. The display element DE1 is thereby formed in the subpixel SP1. This etching process may include wet etching and dry etching processes which are performed in order for the sealing layer SE11, the cap layer CP1, the upper electrode UE1, and the organic layer OR1. After these etching processes, the resist R3 is removed (peeled off).

Incidentally, the stacked film FL1 located under the sealing layer SE11 on the partition 6 is also removed in wet etching for the stacked film FL1. A gap is thereby formed between the sealing layer SE11 located above the partition 6 and the partition 6. Since the stacked film FL1 which constitutes the display element DE1 is completely surrounded by the sealing layer SE11 and the partition 6, the stacked film FL1 is not corroded by the above-described wet etching.

After that, a process for forming the display element DE2 is performed. The display element DE2 can be formed by the same procedure as that of the display element DE1. In other words, when the display element DE2 is formed, the stacked film FL2 and the sealing layer SE12 are formed in the entire mother substrate MB. The stacked film FL2 includes the organic layer OR2 which is in contact with the lower electrode LE2 through the pixel aperture AP2, the upper electrode UE2 which covers the organic layer OR2, and the cap layer CP2 which covers the upper electrode UE2, as shown in FIG. 3.

The organic layer OR2, the upper electrode UE2, and the cap layer CP2 can be formed by, for example, vapor deposition. In addition, the sealing layer SE12 can be formed by, for example, CVD. The stacked film FL2 is divided into a plurality of parts by the partitions 6 and 7A having an overhang shape. The sealing layer SE12 continuously covers each of the divided parts of the stacked film FL2 and the partitions 6 and 7A. By patterning these stacked film FL2 and sealing layer SE2, the display element DE2 is formed in the subpixel SP2 as shown in FIG. 13I.

After that, a process for forming the display element DE3 is performed. The display element DE3 can be formed by the same procedure as the procedures of the display elements DE1 and DE2. In other words, when the display element DE3 is formed, the stacked film FL3 and the sealing layer SE13 are formed in the entire mother substrate MB. The stacked film FL3 includes the organic layer OR3 which is in contact with the lower electrode LE3 through the pixel aperture AP3, the upper electrode UE3 which covers the organic layer OR3, and the cap layer CP3 which covers the upper electrode UE3, as shown in FIG. 3.

The organic layer OR3, the upper electrode UE3, and the cap layer CP3 can be formed by, for example, vapor deposition. In addition, the sealing layer SE13 can be formed by, for example, CVD. The stacked film FL3 is divided into a plurality of parts by the partitions 6 and 7A having an overhang shape. The sealing layer SE13 continuously covers each of the divided parts of the stacked film FL3 and the partitions 6 and 7A. By patterning these stacked film FL3 and sealing layer SE13, the display element DE3 is formed in the subpixel SP3 as shown in FIG. 13J.

It is assumed here that the display elements DE1, DE2, and DE3 are formed in this order. However, the display elements DE1, DE2, and DE3 may be formed in the other order.

After that, the resin layer RS1 is formed as shown in FIG. 13K. The resin layer RS1 can be formed inside the dam structure DS1 by, for example, an ink-jet method. After that, the sealing layer SE2 is formed by, for example, CVD.

After that, the touch panel electrodes TP and the touch panel line TPL are formed on the sealing layer SE2. Furthermore, the resin layer RS2 covering the sealing layer SE2 is formed. The resin layer RS2 can be formed inside the dam structure DS2 by, for example, an ink-jet method. The dam structure DS2 functions to dam up the resin layer RS2 to be cured.

After that, the mother substrate MB is cut along the cut line CL1. Furthermore, the panel portion PP is cut along the cut line CL2. The display device DSP is thereby completed.

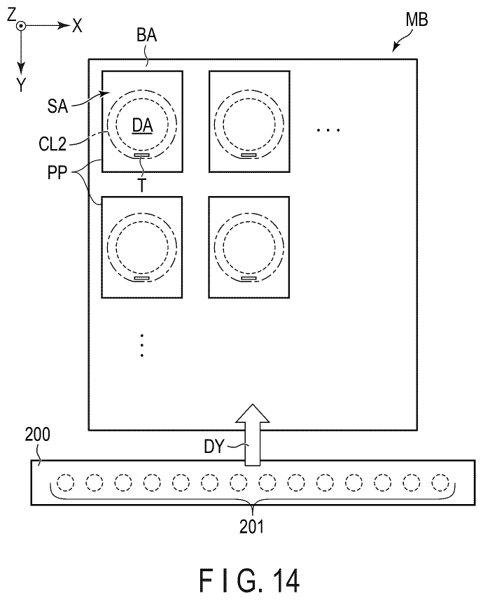

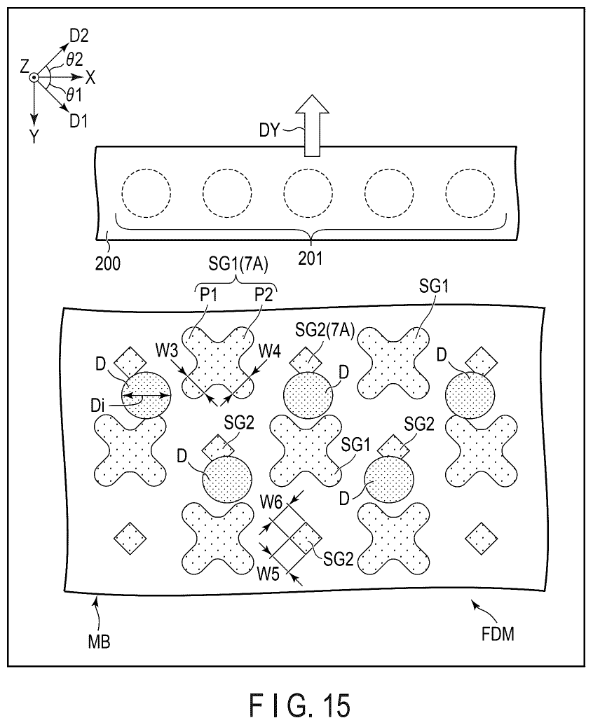

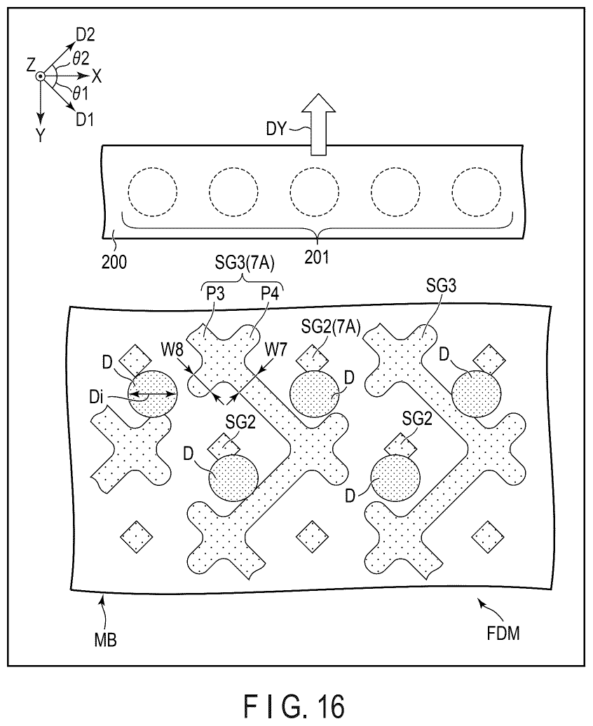

FIG. 14, FIG. 15, and FIG. 16 are diagrams illustrating an applying method of the resin layer RS1 of the display device DSP according to the first embodiment. FIG. 15 shows a case of applying a material to the area where the first segment SG1 of the frame dummy area FDM is provided. FIG. 16 shows a case of applying a material to the area where the third segment SG3 of the frame dummy area FDM is provided.

In the example shown in FIG. 14, the coating device 200 for applying the resin layer RS1 has a plurality of nozzles 201 arranged in the X-direction.

The coating device 200 moves along a coating direction DY parallel to the Y-direction while discharging the material of the resin layer RS1 toward the mother substrate MB. Incidentally, the mother substrate MB may move toward the fixed application device 200 in the Y-direction.

In the other example, the coating device 200 may have a plurality of nozzles 201 arranged in the Y-direction. In this case, the coating device 200 moves in the X-direction while ejecting the material of the resin layer RS1 toward the mother substrate MB.

As shown in FIG. 15 and FIG. 16, the coating device 200 moves along the coating direction DY while dropping droplets D that form the resin layer RS1. The dropped droplets D spread on the mother substrate MB and are hardened, and the resin layer RS1 shown in FIG. 7 is thereby formed.

In the example shown in FIG. 15, the diameter Di of the droplets D is larger than the width W3 of the first portion P1 and the width W4 of the second portion P2 of the first segment SG1 (D1>W3, W4). In addition, the diameter Di of the droplets D is larger than the width W5 and the width W6 of the second segments SG2 (D1>W5, W6).

In the example shown in FIG. 16, the diameter Di of the droplets D is larger than the width W7 of the third portions P3 and the width W8 of the fourth portion of the third segments SG3 (D1>W7, W8).

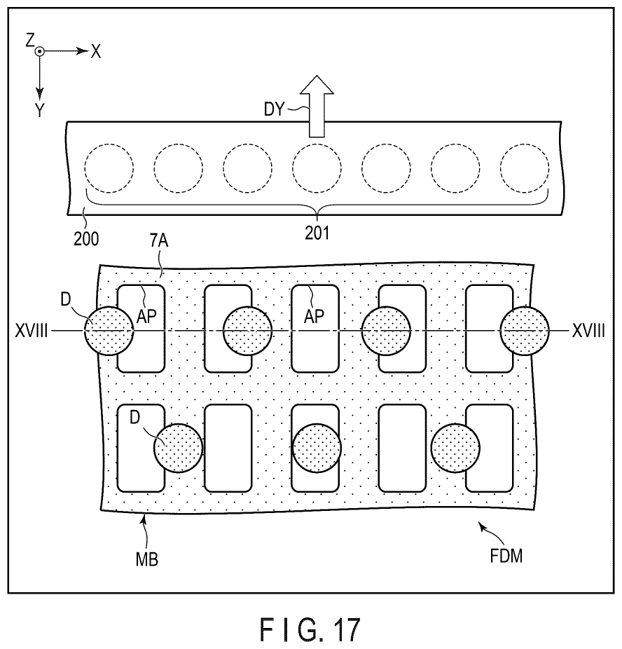

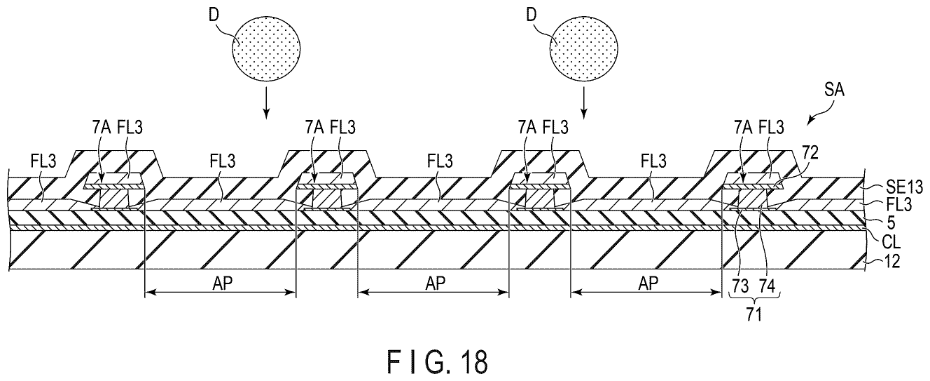

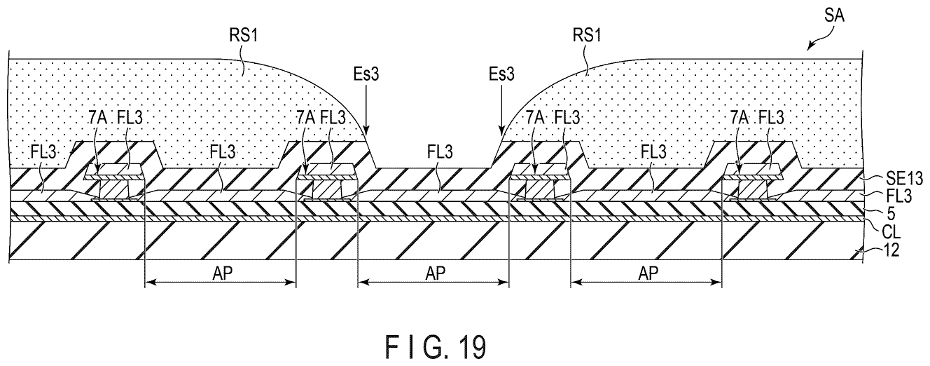

FIG. 17 is a schematic plan view showing a frame dummy area DSP of the display device DSP according to the comparative example. FIG. 18 and FIG. 19 are schematic cross-sectional views showing the display device DSP according to the comparative example along XVIII-XVIII line in FIG. 17.

As shown in FIG. 17, in the display device DSP of the comparative example, the partition 7A provided in the frame dummy area FDM is formed in a grating shape. The partition 7A has a plurality of apertures AP arranged in the X-direction and the Y-direction. In the example shown in FIG. 17, the apertures AP have a rectangular shape elongated in the Y-direction.

A process of forming the resin layer RS1 of the display device DSP according to the comparative example will be described. As shown in FIG. 17 and FIG. 18, the coating device 200 is moved in the coating direction DY to drop the droplets D from the nozzles 201. At this time, the droplets D may not be dropped on several apertures AP, depending on the pitch of the plurality of nozzles 201, the pitch and size of the apertures AP, and the like. In such cases, as shown in FIG. 19, the spreading of droplets D may be hindered by surface tension near edges Es3 of the sealing layer SE13. As a result, the resin layer RS1 may not be normally formed near several apertures AP, and large steps may be thereby generated. The steps may adversely affect the formation of layers located above the resin layer RS1, and may cause, for example, breakage of the touch panel line TPL or short circuit.

In the present embodiment, the partition 7A provided in the frame dummy area FDM includes a plurality of first segments SG1 formed in a cross shape. Since the plurality of first segments SG1 are spaced apart from each other, the partition 7A does not have apertures such as the apertures AP of the comparative example. Therefore, no steps are generated due to the formation failure of the resin layer RS1. As a result, each layer located above the resin layer RS1 is normally formed, enabling the yield to be improved. In addition, since the apertures AP of the comparative example are not formed in the plurality of third segments SG3, the same effect can be obtained.

In addition, the stacked films FL1, FL2, and FL3 formed by vapor deposition may have poor adhesion to the base. Therefore, the stacked films FL1, FL2, and FL3 and the sealing layers SE11, SE12, and SE13 which cover these stacked films may be peeled off from the base when the display device DSP is manufactured.

The peeling easily occurs in a case where the stacked films FL1, FL2, and FL3 are continuously formed in a wide range. In the display area DA and the dummy pixel area DMY, the stacked films FL1, FL2, and FL3 are divided into pieces by the partition 6. The peeling is therefore suspended.

In addition, in the present embodiment, the plurality of first segments SG1, the plurality of second segments SG2, and the plurality of third segments SG3 are provided in the frame dummy area FDM. Accordingly, the direction of the stress which causes the peeling is dispersed, and the peeling is suspended.

Furthermore, the plurality of first segments SG1 and the plurality of second segments SG2 are arranged at regular pitches in the X-direction and the Y-direction. Accordingly, the direction of the stress which causes the peeling is equally dispersed, and the peeling is more suspended.

### Second Embodiment

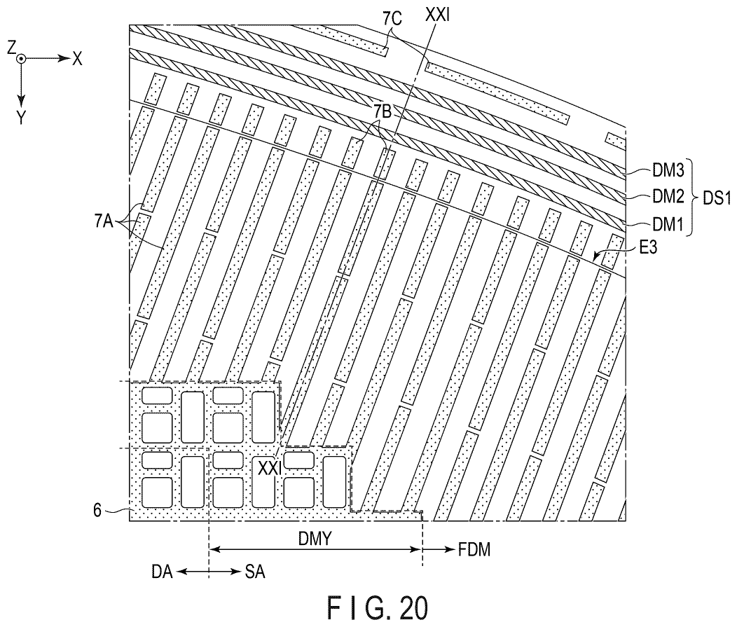

Next, a second embodiment will be described. FIG. 20 is a schematic plan view showing a display device DSP according to the second embodiment with an area surrounded by a frame V in FIG. 4 enlarged. The elements which are the same as or similar to the elements of the first embodiment are denoted by the same reference numerals, and duplicated descriptions are omitted as appropriate.

Partitions 7A and 7B of the second embodiment extend in a straight line. As described in detail later, the partitions 7A and 7B extend radially from a center of a substrate 10. In the example shown in FIG. 20, a plurality of partitions 7A are arranged in a straight line. The partitions 7B are arranged in a straight line with the partitions 7A and are spaced apart from the partitions 7A by end portions E3 provided therebetween.

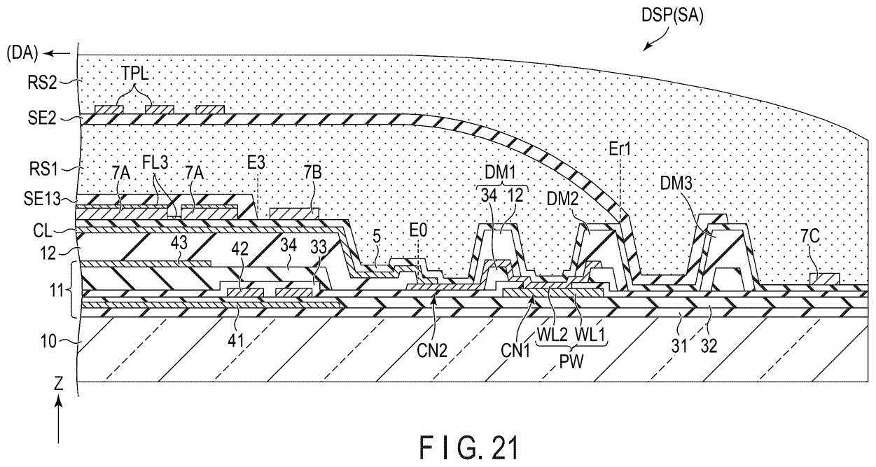

FIG. 21 is a schematic cross-sectional view showing the display device DSP according to the second embodiment along XXI-XXI line in FIG. 20. In the display device DSP of the second embodiment as well, a stacked film FL3 is provided on the partitions 7A and between the partitions 7A spaced apart from each other, similarly to the first embodiment. In addition, the partitions 7A and the stacked film FL3 are covered with a sealing layer SE13, a resin layer RS1, a sealing layer SE2, and a resin layer RS2.

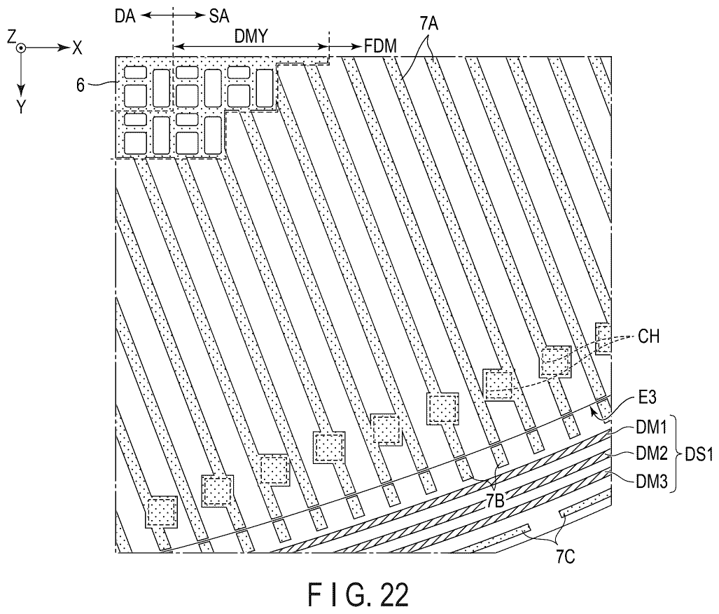

FIG. 22 is a schematic plan view showing the display device DSP according to the second embodiment with an area surrounded by a frame VIII in FIG. 4 enlarged. Parts of the partitions 7A overlap with contact holes CH. In addition, the partitions 7A are connected to a partition 6 of a dummy pixel area DMY. Therefore, a common voltage supplied to terminal portion T is supplied to the partitions 7A overlapping with the contact holes CH via the contact holes CH, and then supplied from the partitions 7A to the partition 6 and upper electrodes UE1, UE2, and UE3.

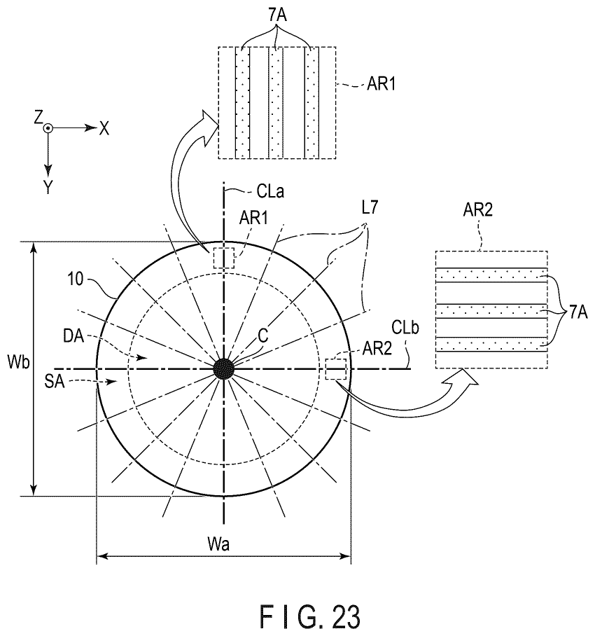

FIG. 23 is a diagram illustrating an extension direction of the partitions 7A. The partitions 7A extend along straight lines L7 that radiate from the center C of the substrate 10. The center C corresponds to an intersection of a center line CLa of a width Wa of the substrate 10 in the X-direction and a center line CLb of a width Wb of the substrate 10 in the Y-direction. As shown in FIG. 23, when the substrate 10 has a circular shape, the center of the circle corresponds to the center C.

The extension directions of the partitions 7A in a first area AR1 located on center line CLa and a second area AR2 located on the center line CLb will be compared. The first area AR1 and the second area AR2 are provided in a surrounding area SA. As shown and enlarged in the upper part of FIG. 23, the partitions 7A extend in the Y-direction in the first area AR1. In addition, as shown and enlarged in the right side of FIG. 23, the partitions 7A extend in the X-direction in the second area AR2. In other words, the extension direction (Y-direction) of the partitions 7A in the first area AR1 is different from the extension direction (X-direction) of the partitions 7A in the second area AR2.

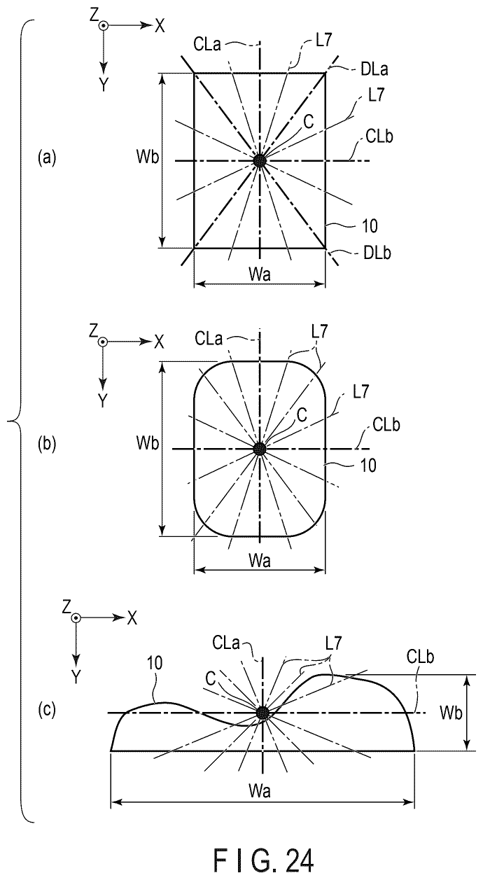

FIG. 24 is a diagram showing a plurality of examples of the substrates 10 having different shapes. The substrate 10 shown in FIG. 24(a) is formed in a rectangular shape elongated in the Y-direction. The substrate 10 shown in FIG. 24(b) is formed in a rectangular shape with rounded corners. The substrate 10 shown in FIG. 24(c) is formed in a shape which is asymmetrical in each of the X-direction and the Y-direction.

In these substrates 10 as well, the center C corresponds to the intersection of the center line CLa of the width Wa of the substrate 10 in the X-direction and the center line CLb of the width Wb of the substrate 10 in the Y-direction. The partition 7A extends along a straight line L7 extending radially from the center C of the substrate 10. In addition, as shown in FIG. 24(a), when the substrate 10 has a rectangular shape, the center C corresponds to the intersection of diagonals DLa and DLb.

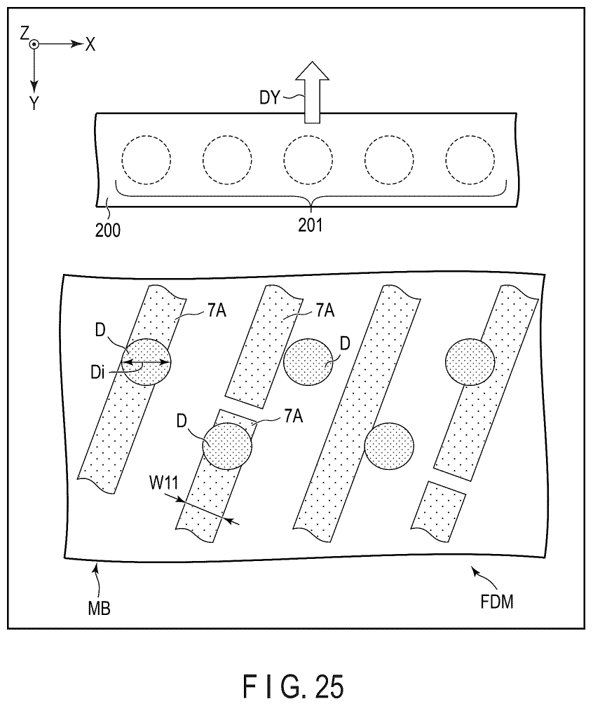

FIG. 25 is a diagram illustrating a method of applying a resin layer RS1 of the display device DSP according to the second embodiment. FIG. 25 shows a case of applying a material to the area where the partitions 7A of the frame dummy area FDM are provided.

In the second embodiment as well, similarly to the first embodiment, droplets D forming the resin layer RS1 are dropped from nozzles 201 of a coating device 200. In the example shown in FIG. 25, a diameter Di of the droplets D is larger than a width W11 of the partitions 7A (D1>W11).

In the present embodiment, partitions 7A extend radially from the center C. In other words, the partitions do not have the apertures AP of the comparative example, similarly to the first embodiment. Therefore, the spread of the droplets D is not hindered by the apertures AP, and the resin layer RS1 can be formed normally. As a result, the yield can be improved.

In addition, a plurality of partitions 7A are arranged in a straight line. In other words, gaps are formed between the adjacent partitions 7A. The direction of stress which causes peeling of the stacked film FL3 can be dispersed by the gaps, thereby suppressing the peeling.

### Third Embodiment

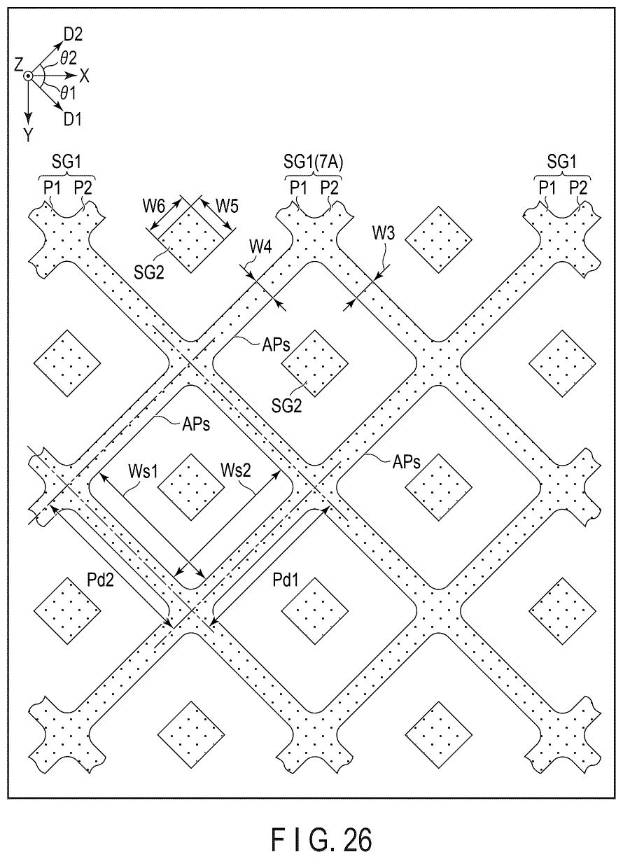

FIG. 26 is a schematic plan view showing a first segment SG1 and a second segment SG2 of a display device DSP according to a third embodiment.

In the third embodiment, the first segment SG1 is formed in a grating pattern. More specifically, a plurality of first portions P1 extending in a direction D1 (first direction) and a plurality of second portions P2 extending in a direction D2 (second direction) intersect.

A pitch Pd1 of the first portions P1 adjacent in the direction D2 is equal to a pitch Pd2 of the second portions P2 adjacent in the direction D1 (Pd1 =Pd2). In the example shown in FIG. 26, the plurality of first portions P1 and the plurality of second portions P2 are arranged at regular pitches. In one example, the pitches Pd1 and Pd2 in the third embodiment shown in FIG. 26 are larger than the pitches Pd1 and Pd2 in the first embodiment shown in FIG. 6.

In the third embodiment, a width W3 of the first portion P1 in the direction D2 is equal to a width W4 of the second portion P2 in the direction D1 (W3=W4). In addition, a width W5 of the second segment SG2 in the direction D1 is equal to a width W6 of the second segment SG2 in the direction D2 (W5=W6). Furthermore, the width W5 and W6 is larger than or equal to the width W3 and W4 (W5, W6>W3, W4). In one example, the width W5 and W6 is approximately twice the width W3 and W4.

The first segment SG1 includes a plurality of apertures APs surrounded by a plurality of first portions P1 and a plurality of second portions P2. In the example shown in FIG. 26, the width Ws1 of the aperture APs in the direction D1 is greater than the width W4 of the second portion P2 in the direction D1 (Ws1>W4). In addition, the width Ws2 of the aperture APs in the direction D2 is greater than the width W3 of the first portion P1 in the direction D2 (Ws1>W3). The second segment SG2 is provided in the center of the aperture APs.

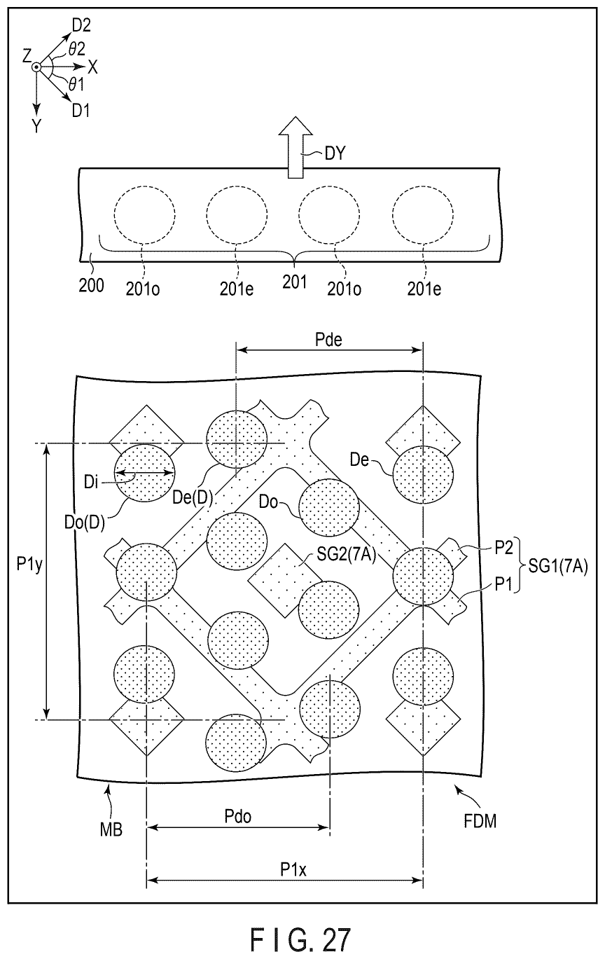

FIG. 27 is a diagram illustrating a method of applying a resin layer RS1 of the display device DSP according to the third embodiment. FIG. 27 shows a case of applying a material to the area where the partitions 7A of the frame dummy area FDM are provided. In the third embodiment as well, similarly to each of the above-described embodiments, droplets D forming the resin layer RS1 are dropped from nozzles 201 of a coating device 200.

The nozzles 201 include a plurality of nozzles 201o located at odd-numbered positions from the end and a plurality of nozzles 201e located at even-numbered positions from the end. The nozzles 201o and 201e are arranged alternately at regular pitches in the X-direction.

The droplets D include droplets Do dropped from the nozzles 201o and droplets De dropped from the nozzles 201e. At this time, a pitch Pdo of the droplets Do adjacent in the X-direction is equal to a pitch Pdo of the droplets De adjacent in the X-direction (Pdo=Pde).

In the third embodiment, pitches P1x and P1y are larger than the pitches Pdo and Pde (P1x, P1y>Pdo, Pde). In one example, the pitches P1x and P1y are approximately 1.5 times the pitches Pdo and Pde.

In the third embodiment, the first segment SG1 is formed in a grating pattern. Therefore, a direction of the stress causing the peeling of the stacked film FL3 is divided into the direction D1 of the first portion P1 and the direction D2 of the second portion P2, thereby suppressing the peeling. In addition, the width W3 of the first portion P1 is equal to the width W4 of the second portion P2. Therefore, the direction of the stress is equally divided into the directions D1 and D2, and the peeling is more suspended.

In addition, in the third embodiment, the pitches P1x and P1y are larger than the pitches Pde and Pdo. Therefore, for example, if a droplet D does not drop from one of the nozzles 201 or the interval between a droplet De and the droplet Do is wider, at least one droplet D drops into the aperture APs. As a result, the resin layer RS1 can be formed normally.

### Fourth Embodiment

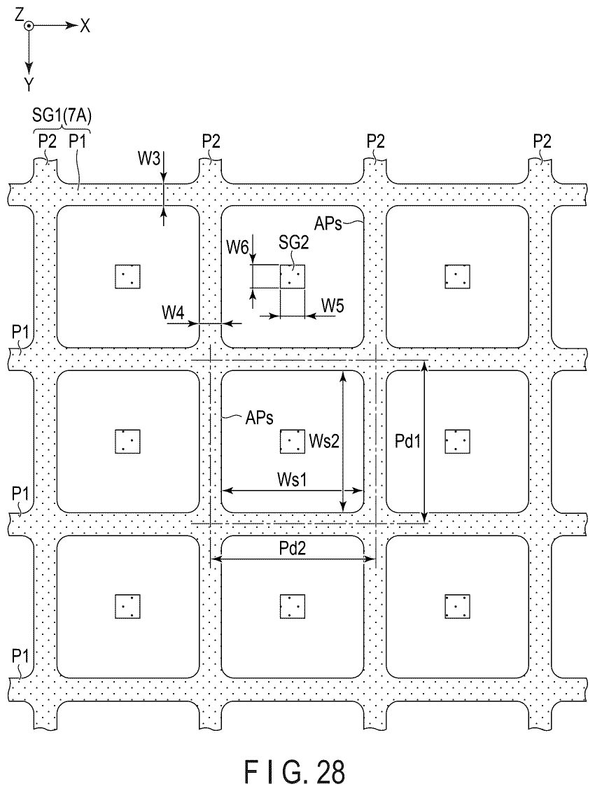

FIG. 28 is a schematic plan view showing a first segment SG1 and a second segment SG2 of a display device DSP according to a fourth embodiment.

In the fourth embodiment, a plurality of first portions P1 extend in the X-direction (first direction), and a plurality of second portions P2 extend in the Y-direction (second direction).

A pitch Pd1 of the first portions P1 adjacent in the Y-direction is equal to a pitch Pd2 of the second portions P2 adjacent in the X-direction (Pd1=Pd2). In the example shown in FIG. 28, the plurality of first portions P1 and the plurality of second portions P2 are arranged at regular pitches.

In the fourth embodiment, a width W3 of the first portion P1 in the Y-direction is equal to a width W4 of the second portion P2 in the X-direction (W3=W4). In addition, a width W5 of the second segment SG2 in the X-direction is equal to a width W6 of the second segment SG2 in the Y-direction (W5=W6). Furthermore, the width W5 and W6 is equal to the width W3 and W4 (W5, W6=W3, W4).

The width W5 and W6 in the fourth embodiment shown in FIG. 28 is equal to the width W5 and W6 in the first embodiment shown in FIG. 6. In addition, the width W5 and W6 in the fourth embodiment is smaller than the width W5 and W6 in the third embodiment shown in FIG. 26. In one example, the width W5 and W6 in the fourth embodiment is approximately half the width W5 and W6 in the third embodiment shown in FIG. 26. Furthermore, the pitches Pd1 and Pd2 in the fourth embodiment are equal to the pitches Pd1 and Pd2 in the first embodiment.

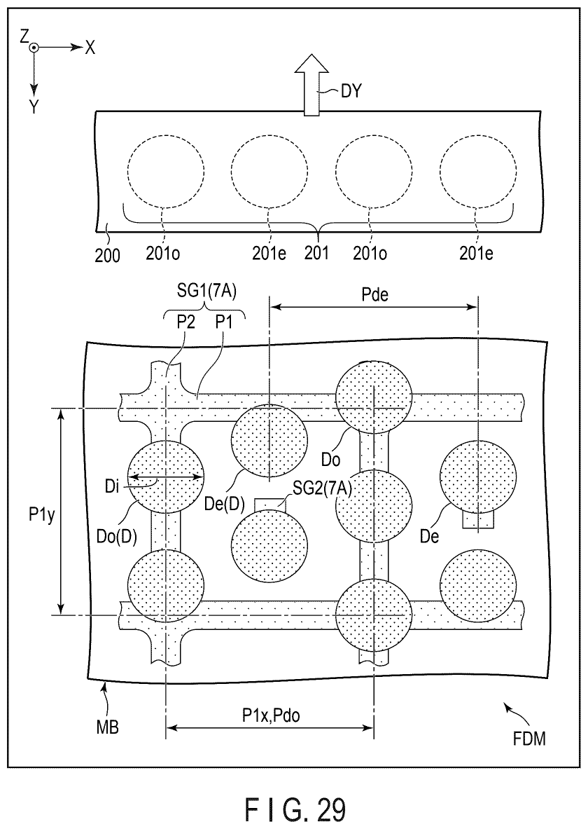

FIG. 29 is a diagram illustrating a method of applying a resin layer RS1 of the display device DSP according to the fourth embodiment.

In the fourth embodiment, pitches P1x and P1y are equal to the pitches Pdo and Pde (P1x, P1y=Pdo, Pde). Incidentally, the pitches P1x and P1y may be larger than the pitches Pdo and Pde (P1x, P1y>Pdo, Pde).

Effects similar to those of each of the above-described embodiments can also be obtained from the fourth embodiment.

### Fifth Embodiment

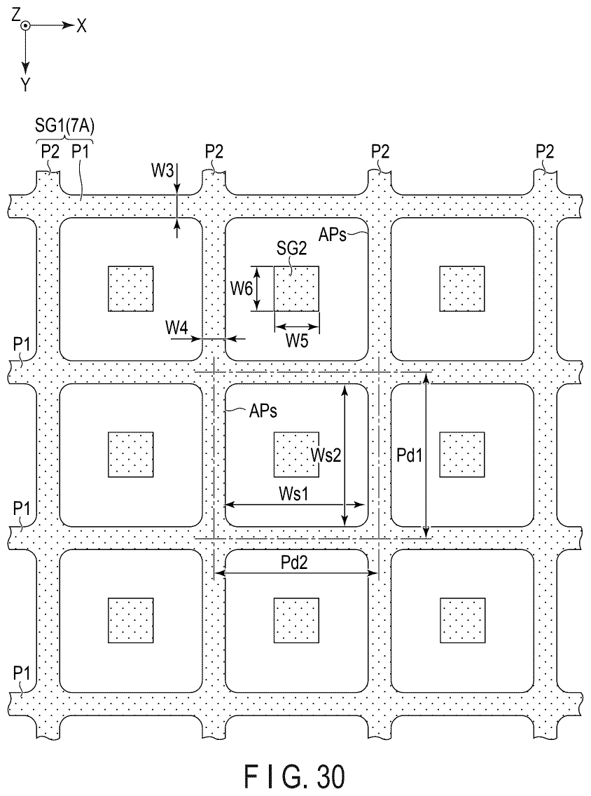

FIG. 30 is a schematic plan view showing a first segment SG1 and a second segment SG2 of a display device DSP according to a fifth embodiment.

In the fifth embodiment, widths W5 and W6 of the second segment SG2 are greater than or equal to the width W3 of the first portion P1 and the width W4 of the second portion P2 (W5, W6>W3, W4). In one example, the width W5 and W6 is approximately twice the width W3 and W4.

The width W5 and W6 in the fifth embodiment shown in FIG. 30 is larger than the width W5 and W6 in the fourth embodiment shown in FIG. 28. In one example, the width W5 and W6 in the fifth embodiment is approximately twice the width W5 and W6 in the fourth embodiment. In addition, the pitches Pd1 and Pd2 in the fifth embodiment are larger than the pitches Pd1 and Pd2 in the fourth embodiment. In one example, the pitches Pd1 and Pd2 in the fifth embodiment are approximately 1.5 times larger than the pitches Pd1 and Pd2 in the fourth embodiment.

Effects similar to those of each of the above-described embodiments can also be obtained from the fifth embodiment.

### Sixth Embodiment

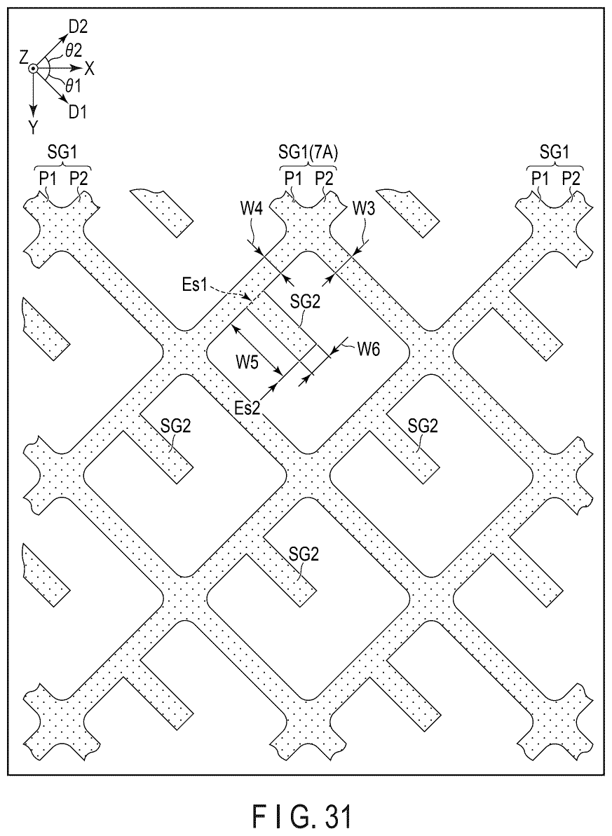

FIG. 31 is a schematic plan view showing first segments SG1 and second segments SG2 of a display device DSP according to a sixth embodiment.

In the sixth embodiment, the second segments SG2 extend in a direction D1. The second segment SG2 is located between the first portions P1 adjacent in a direction D2. In the example shown in FIG. 31, an end portion Es1 of the second segment SG2 is connected to the second portion P2, and an end portion Es2 is spaced apart from the first portion. In addition, the end portion Es2 of the second segment SG2 is located near the center of the aperture APs.

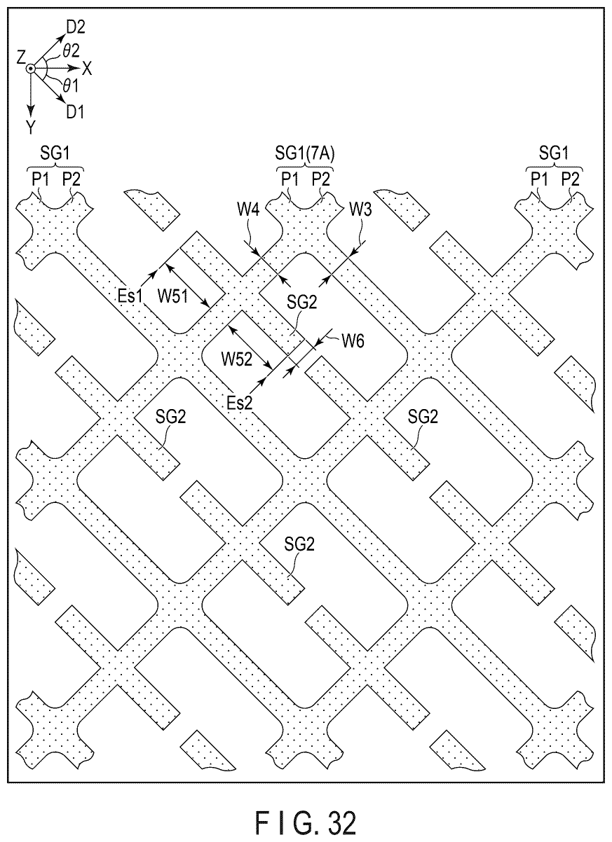

A width W5 of the segment SG2 in the direction D1 is larger than a width W6 of the second segment SG2 in the direction D2 (W5>W6). In the example shown in FIG. 32, the width W6 is equal to the width W3 of the first portion P1 and the width W4 of the second portion P2.

Effects similar to those of each of the above-described embodiments can also be obtained from the sixth embodiment.

### Seventh Embodiment

FIG. 32 is a schematic plan view showing first segments SG1 and second segments SG2 of a display device DSP according to a seventh embodiment.

In the seventh embodiment, the second portion P2 is provided between the end portions Es1 and Es2 of the second segment SG2. In the example shown in FIG. 32, a width W51 between the second portion P2 and the end portion Es1 is equal to a width W52 between the second portion P2 and the end portion Es2 (W51=W52). In addition, the width W51 and W52 is larger than the width W6 (W51, W52>W6).

Effects similar to those of each of the above-described embodiments can also be obtained from the seventh embodiment.

All of the display devices that can be implemented by a person of ordinary skill in the art through arbitrary design changes to the display device described above as the embodiments of the present invention come within the scope of the present invention as long as they are in keeping with the spirit of the present invention.

Various modified examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device comprising:
a display area where images are displayed;
a surrounding area outside the display area;
a lower electrode provided in the display area;
a rib layer provided across the display area and the surrounding area and including a pixel aperture which overlaps with the lower electrode; and
a first partition including a first lower portion provided on the rib layer in the surrounding area and having a conductive property, and a first upper portion provided on the first lower portion to protrude from a side surface of the first lower portion, wherein the first partition includes a plurality of first segments formed in a cross shape and spaced apart from each other, and
the plurality of first segments do not have apertures.

2. The display device of claim 1, wherein
the first partition includes a plurality of second segments spaced apart from the first segments, and
the plurality of first segments and the plurality of second segments are arranged alternately in a first direction, and
the plurality of first segments and the plurality of second segments are arranged alternately in a second direction intersecting the first direction.

3. The display device of claim 2, wherein
the plurality of first segments are arranged at first pitches in the first direction and the second direction,
the plurality of second segments are arranged at second pitches in the first direction and the second direction, and
the first pitches are equal to the second pitches.

4. The display device of claim 1, further comprising:
an organic layer provided on the rib layer in the surrounding area;
an upper electrode provided on the organic layer;
a cap layer provided on the upper electrode; and
a sealing layer provided on the cap layer and covering the first partition.

5. The display device of claim 4, further comprising:
a second partition including a second lower portion provided on the rib layer in the display area and having a conductive property, and a second upper portion provided on the second lower portion to protrude from a side surface of the second lower portion; and
a conductive layer to which a common voltage is supplied, wherein
the second partition surrounds the lower electrode and the pixel aperture,
the rib layer includes a contact hole penetrating the conductive layer in the surrounding area,
the first partition includes a third segment which is in contact with the conductive layer through the contact hole and which is electrically connected to the second partition, and
the third segment has a shape in which the plurality of first segments are connected in a staircase-like manner.

6. A display device comprising:
a substrate having a display area where images are displayed and a surrounding area provided outside the display area;
a lower electrode provided above the substrate in the display area;
a rib layer provided across the display area and the surrounding area and including a pixel aperture which overlaps with the lower electrode; and
a plurality of first partitions including a first lower portion provided on the rib layer in the surrounding area and having a conductive property, and a first upper portion provided on the first lower portion to protrude from a side surface of the first lower portion, wherein
the plurality of first partitions radially extend from intersections of a center line of a width of the substrate in the first direction and a center line of a width of the substrate in a second direction intersecting the first direction.

7. The display device of claim 6, wherein
parts of the plurality of first partitions are arranged in a straight line.

8. The display device of claim 6, further comprising:
an organic layer provided on the rib layer in the surrounding area;
an upper electrode provided on the organic layer;
a cap layer provided on the upper electrode; and
a sealing layer provided on the cap layer and covering the first partition.

9. The display device of claim 8, further comprising:
a second partition including a second lower portion provided on the rib layer in the display area and having a conductive property, and a second upper portion provided on the second lower portion to protrude from a side surface of the second lower portion; and
a conductive layer to which a common voltage is supplied, wherein
the second partition surrounds the lower electrode and the pixel aperture,
the rib layer includes a contact hole penetrating the conductive layer in the surrounding area,
the first partition is in contact with the conductive layer through the contact hole and is electrically connected to the second partition.

10. A display device comprising:
a display area where images are displayed;
a surrounding area outside the display area;
a lower electrode provided in the display area;
a rib layer provided across the display area and the surrounding area and including a pixel aperture which overlaps with the lower electrode; and
a first partition including a first lower portion provided on the rib layer in the surrounding area and having a conductive property, and a first upper portion provided on the first lower portion to protrude from a side surface of the first lower portion, wherein
the first partition includes a first segment formed in a grating shape and including a plurality of first portions extending in a first direction and arranged at regular pitches in a second direction intersecting the first direction, a plurality of second portions extending in the second direction and arranged at regular pitches in the first direction, and a plurality of apertures surrounded by the plurality of first portions and the plurality of second portions, and
a width of the first portion in the second direction is equal to a width of the second portion in the first direction.

11. The display device of claim 10, wherein
a width of the aperture in the second direction is larger than a width of the first portion in the second direction, and
a width of the aperture in the first direction is larger than a width of the second portion in the first direction.

12. The display device of claim 10, wherein
the first partition includes a plurality of second segments spaced apart from the first segments, and
the second segments are provided in the center of the apertures.

13. The display device of claim 12, wherein
a width of the second segment in the first direction is larger than or equal to a width of the second portion in the first direction, and
a width of the second segment in the second direction is larger than or equal to a width of the first portion in the second direction.

14. The display device of claim 10, further comprising:
a second segment extending in the first direction and provided between the adjacent first portions, wherein
an end of the second segment is connected to the second portion, and
the other end of the second segment is spaced apart from the second portion.

15. The display device of claim 14, wherein
a width of the second segment in the second direction is equal to a width of the first portion in the second direction and a width of the second portion in the first direction.

16. The display device of claim 10, further comprising:
a second segment extending in the first direction and provided between the adjacent first portions, wherein
the second portion is provided between both ends of the second segment.
